(19) United States
(12) Patent Application Publication
(10) Pub. No.: US 2025/0185163 A1
(43) Pub. Date: Jun. 5, 2025

(54) ORGANIC-TO-INORGANIC BONDING METHODS AND STRUCTURES

(71) Applicant: ADEIA SEMICONDUCTOR BONDING TECHNOLOGIES INC., San Jose, CA (US)

(72) Inventors: Oliver Zhao, Sunnyvale, CA (US); Bongsub Lee, Santa Clara, CA (US); Cyprian Emeka Uzoh, San Jose, CA (US); Belgacem Haba, Saratoga, CA (US)

(21) Appl. No.: 18/530,096

(22) Filed: Dec. 5, 2023

(51) Int. Cl. H05K 1/03; H05K 3/06; H05K 3/38

(52) U.S. Cl. CPC H05K 1/036; H05K 3/064; H05K 3/389; H05K 2201/0154

(57) ABSTRACT

Disclosed herein are bonded structures and methods of forming the bonded structures. In some embodiments, the bonded structures include a first element having an inorganic dielectric surface, a second element having an organic dielectric surface, an interface layer between the first and second elements and bonded to the inorganic and organic dielectric surfaces. The method of forming the bonded structure includes providing the first and second elements, exposing the inorganic dielectric surface to a silane coupling agent to form the interface layer, contacting the organic dielectric surface to the interface layer, and heating the first element, second element, and interface layer to bond the first element to the second element.

### BACKGROUND

### Field

The field relates to methods of bonding an organic bonding surface to an inorganic bonding surface, and associated structures thereof.

### Description of the Related Art

Many system substrates (e.g., printed circuit boards (PCBs), flexible substrates, etc.) typically include a substrate and one or more microelectronic components (e.g., dies, die-containing packages, etc.) attached to the system substrate. The PCB substrates have an outer surface defined by an organic layer (e.g., a polymer-based layer such as a polyimide layer) and exposed conductive traces/terminals that forms a surface on which the one or more die-containing packages are attached. In conventional PCBs, the packages each include a package substrate and one or more dies attached to the substrate, which is then bonded to the PCB (e.g., with solder and/or an adhesive). The package substrate includes metallization structures (e.g., vias, bond pads, bridges) that facilitate communication between the individual dies within the package and also between the dies and PCB substrate. Solder balls electrically connect the dies to the metallization structures in the PCB substrate. However, solder balls are comparatively large and require a large pitch size between adjacent solder balls, which means that the density of I/O connections between the dies and the PCB substrate are limited. As dies get smaller and more complex, the need for higher density I/O connections to the dies increases. Additionally, in conventional systems, the package substrate, which is needed to attach the dies to the PCB substrate, has a relatively large footprint, which reduces the number of dies that can be attached to the PCB substrate. Accordingly, there is a need for an improved way of bonding dies to a PCB substrate that facilitates electrical connection between the dies and metallization structures in the PCB substrate.

### BRIEF DESCRIPTION OF THE DRAWINGS

FIG. 1A is a schematic side sectional view of two elements bonded together with a uniform inorganic-to-organic bond, according to some embodiments.

FIG. 1B is a schematic side sectional view of two elements bonded together with a hybrid inorganic-to-organic bond, according to some embodiments.

FIG. 2 is a flowchart illustrating a process of forming a bonded structure that includes an inorganic-to-organic bond, according to some embodiments.

FIG. 3 is a flowchart illustrating a process of forming a bonded structure that includes an inorganic-to-organic bond, according to some embodiments.

FIGS. 4A-4F are schematic side sectional views of elements at various stages of a process like that of FIG. 3.

FIG. 5 is a flowchart illustrating a process of forming a bonded structure that includes a hybrid inorganic-to-organic bond, according to some embodiments.

FIGS. 6A-6I are schematic side sectional views of elements at various stages of a process like that of FIG. 5.

FIG. 7 is a flowchart illustrating a process of forming a bonded structure that includes a hybrid inorganic-to-organic bond, according to some embodiments.

FIGS. 8A-8D are schematic side sectional views of elements at various stages of a process like that of FIG. 7.

FIG. 9A is a schematic side sectional view of a printed circuit board, according to an embodiment.

FIG. 9B is a schematic side sectional view of a printed circuit board that includes an inorganic-to-organic bond between one or more dies and the printed circuit board substrate, according to embodiments.

### DETAILED DESCRIPTION

Various embodiments disclosed herein relate to bonded structures in which an element having an organic bonding surface is bonded to an element having an inorganic bonding surface (referred to herein as “inorganic-to-organic bonding” processes). Inorganic-to-organic bonding can involve bonding an inorganic material on the bonding surface of a first element to an interface layer formed on the inorganic material and then bonding organic material on the bonding surface of a second element (also referred to as “uniform” inorganic-to-organic bonding) to the interface layer. Inorganic-to-organic bonding can also involve bonding of multiple materials on one element to multiple materials on the other element (e.g., “hybrid” inorganic-to-organic bonding). Hybrid inorganic-to-organic bonding is a species of bonding in which the nonconductive features on the first and second elements are both bonded to an interface layer formed between the first and second elements while the conductive features on the first element directly bond to conductive features on the second element.

In some implementations, the inorganic bonding layer can be formed from one material while the organic bonding layer can be formed from a different material. For example, in some embodiments, the inorganic and organic bonding layers can be unpatterned such that the bonding surface of each element includes a blanket deposited material. In other embodiments, however, the bonding layers can be patterned on one or both elements such that the bonding layers include conductive features exposed at the bonding surfaces and that may be at least partially surrounded by non-conductive dielectric field regions within their respective bonding layers.

In some implementations of uniform bonding, where both of the bonding layers are unpatterned, the inorganic material that forms the inorganic bonding layer and the organic material that forms the organic bonding layer can be the only portions of the first and second elements that are involved in bonding the first and second elements together (e.g., there are no conductive direct bonds between the elements). In such uniform bonding processes, one or both of the bonding layers may be without any conductive features patterned therein. In another implementation of uniform bonding, one or both of the bonding layers may include one or more conductive features, but the conductive features are not involved in the bonding.

In some implementations of hybrid bonding, the inorganic and organic bonding layers are each patterned and include conductive contact features. During hybrid bonding, while the inorganic bonding surface and the organic bonding surfaces are both bonded to the interface layer, the conductive contact features may directly bond to one another without an intervening adhesive or an intervening layer.

In various embodiments, the inorganic bonding layer can comprise an inorganic non-conductive material such as an inorganic dielectric material or an undoped semiconductor material, such as undoped silicon, which may include native oxide. Suitable inorganic dielectric materials include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon.

In some embodiments, the organic bonding layers comprise an organic non-conductive material, including polymer materials such as epoxy (e.g., epoxy adhesives, cured epoxies, or epoxy composites such as FR-4 materials), resin or molding materials. In some embodiments, the organic bonding layers comprise polyimide.

As explained herein, first and second elements can be bonded to one another with an interface layer, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between the bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interfaces (e.g., the interface between the inorganic bonding layer and the interface layer and the interface between the organic bonding layer and the interface layer) can include concentration of materials from the activation and/or last chemical treatment processes. For example, in embodiments that utilize an oxygen plasma and/or a water vapor plasma for activation, an oxygen concentration peak can be formed at the bond interfaces.

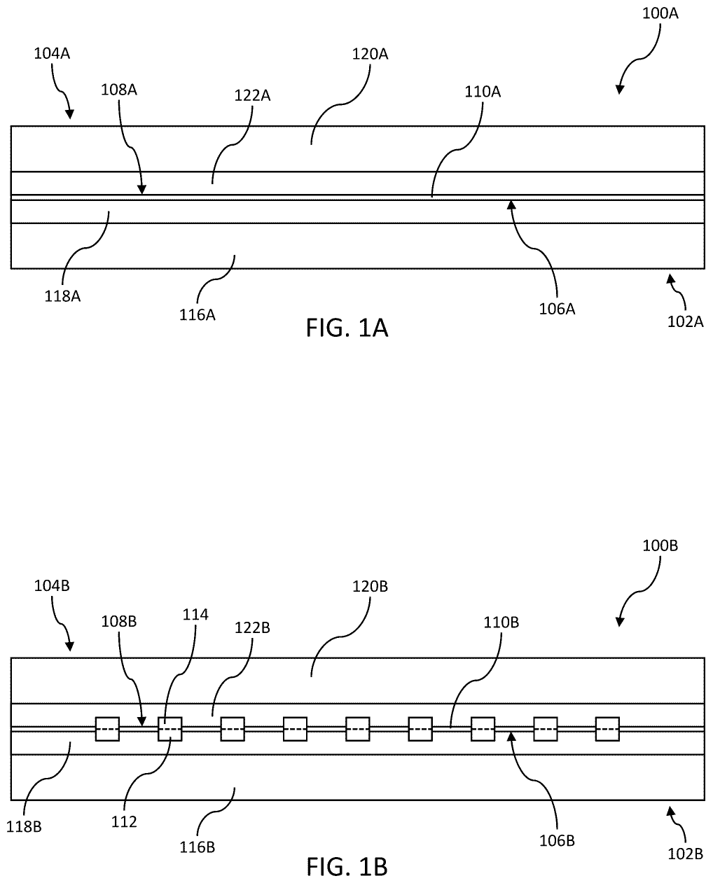

FIGS. 1A and 1B schematically illustrate cross-sectional side views of bonded structures 100A, 100B that incorporate inorganic-to-organic bonding, where bonded structure 100A illustrates a uniform inorganic-to-organic bonding and bonded structure 100B illustrates hybrid inorganic-to-organic bonding. The bonded structures 100A, 100B each include first elements 102A, 102B having inorganic bonding surfaces 106A, 106B, and second elements 104A, 104B having organic bonding surfaces 108A, 108B. The bonded structures 100A, 100B each also includes interface layers 110A, 110B that are formed between the first elements 102A, 102B and the second elements 104A, 104B and that are bonded to the inorganic bonding surfaces 106A, 106B and the organic bonding surfaces 108A, 108B. As discussed in greater detail elsewhere in the application, the interface layers 110A, 110B can be formed by depositing a silane coupling agent on the exposed inorganic bonding surfaces, and the bonded structures 100A, 100B can be formed by bonding the organic bonding surfaces 108A, 108B of the second elements 104A, 104B to the interface layers 110A, 110B. Accordingly, the interface layer 110A, 110B facilitate the formation of an inorganic-to-organic bond between the first elements 102A, 102B and the second elements 104A, 104B.

While the first and second elements 102A, 104A of the first bonded structure 100A are bonded together with a uniform inorganic-to-organic bond, the first and second elements 102B, 104B of the bonded structure 100B each include conductive features 112, 114 that are directly bonded to each other (e.g., without an intervening adhesive between the conductive features 110, 112) to form a hybrid inorganic-to-organic bond. Conductive features 112 (e.g., contact pads, traces, electrodes, exposed ends of vias or through substrate vias (TSVs)) of the first element 102B may be electrically connected to corresponding conductive features 114 of the second element 104B.

The first elements 102A, 102B can include inorganic bonding layers 118A, 118B formed on base substrate portions 116A, 116B, where the inorganic bonding layers 118A, 118B at least partially define the inorganic bonding surfaces 106A, 106B. Similarly, the second elements 104A, 104B can include organic bonding layers 122A, 122B formed on base substrate portions 120A, 120B, where the organic bonding layers 122A, 122B at least partially define the organic bonding surfaces 108A, 108B. In various embodiments, the interface layers 110A, 110B can bond the inorganic bonding layers 118A, 118B of the first elements 102A, 102B, to the organic bonding layers 122A, 122B of the second elements 104A, 104B. The inorganic bonding layers 118A, 118B can be disposed on the front sides of their respective base substrate portions 116A, 116B. Similarly, the organic bonding layers 122A, 122B can be disposed on the front sides of their respective base substrate portions 120A, 120B.

The first elements 102A, 102B can comprise microelectronic elements such as semiconductor elements, including, for example, integrated device dies, wafers, passive devices, individual active devices such as power switches, MEMS, etc. In some embodiments, the base substrate portions 116A, 116B of the first elements 102A, 102B can comprise a device portion, such as a bulk semiconductor (e.g., silicon) portion of the first elements 102A, 102B or back-end-of-line (BEOL) interconnect layers over such semiconductor portions. The inorganic bonding layers 118A, 118B can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 116A, 116B. Active devices and/or circuitry can be disposed at or near the front sides of the base substrate portions 116A, 116B, and/or at or near opposite backsides of the base substrate portions 116A, 116B. In other embodiments, the base substrate portions 116A, 116B may not include active circuitry, but may instead comprise dummy substrates, interposers, passive optical elements (e.g., glass substrates, gratings, lenses), etc. The inorganic bonding layers 118A, 118B and organic bonding layers 122A, 122B are shown as being provided on the front sides of their respective elements, but similar bonding layers can be additionally or alternatively be provided on the back sides of the elements.

In some embodiments, the base substrate portions 116A, 116B, 120A, 120B can have significantly different coefficients of thermal expansion (CTEs), and bonding elements that include such different based substrate portions can form a heterogenous bonded structure. The CTE difference between the base substrate portions 116A, 116B, 120A, 120B, and particularly between bulk semiconductor, (typically single crystal) portions of the base substrate portions 116A, 116B, 120A, 120B, can be greater than 5 ppm/° C. or greater than 10 ppm/° C. For example, the CTE difference between the base substrate portions 116A, 116B, 120A, 120B can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 116A, 116B, 120A, 120B can comprise optoelectronic single crystal materials, including perovskite materials, that are useful for optical piezoelectric or pyroelectric applications, and the other of the base substrate portions 116A, 116B, 120A, 120B comprises a more conventional substrate material. For example, one of the base substrate portions 116A, 116B, 120A, 120B comprises lithium tantalate (LiTaO3) or lithium niobate (LiNbO3), and the other one of the base substrate portions 116A, 116B, 120A, 120B comprises silicon (Si), quartz, fused silica glass, sapphire, or a glass. In other embodiments, one of the base substrate portions 116A, 116B, 120A, 120B comprises a III-V single semiconductor material, such as gallium arsenide (GaAs) or gallium nitride (GaN), and the other one of the base substrate portions 116A, 116B, 120A, 120B can comprise a non-III-V semiconductor material, such as silicon (Si), or can comprise other materials with similar CTE, such as quartz, fused silica glass, sapphire, or a glass. In still other embodiments, one of the base substrate portions 116A, 116B, 120A, 120B comprises a semiconductor material and the other of the base substrate portions 116A, 116B, 120A, 120B comprises a packaging material, such as a glass, organic or ceramic substrate.

In some embodiments, at least one of the base substrate portions 116A, 116B, 120A, 120B can comprise an organic or inorganic substrate. For example, in some embodiments, the base substrate portions 116A, 116B of the first elements 102A, 102B can comprise an organic or inorganic material and the inorganic bonding layers 118A, 118B can be formed on the organic or inorganic base substrate portions 116A, 116B (e.g., a package substrate including one or more organic or ceramic materials). Similarly, in some embodiments, the base substrate portions 120A, 120B of the second elements 104A, 104B can comprise an organic or inorganic material and the organic bonding layers 122A, 122B can be formed on the organic or inorganic base substrate portions 120A, 120B. Additional details regarding organic or inorganic substrates may be found throughout the specification. In some arrangements, the first elements 102A, 102B can comprise a singulated element, such as a singulated integrated device die. In other arrangements, the first elements 102A, 102B can comprise a carrier or substrate (e.g., a wafer) that includes a plurality (e.g., tens, hundreds, or more) of device regions that, when singulated, form a plurality of integrated device dies. In some embodiments, the second elements 104A, 104B can comprise a printed circuit board or a polymeric substrate.

Any suitable number of elements can be stacked in the bonded structures 100A, 100B. For example, a third element (not shown) can be stacked on the second elements 104A, 104B, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first elements 102A, 102B. In some embodiments, a laterally stacked additional element may be smaller than the second elements. In some embodiments, the laterally stacked additional element may be two times smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate high quality and high strength bonds between the inorganic bonding layers 118A, 118B and the corresponding interface layers 110A, 110B, the bonding surfaces 106A, 106B of the inorganic bonding layers 118A, 118B can be prepared for bonding before the interface layers 110A, 110B are formed on the inorganic bonding layers 118A, 118B. The inorganic bonding surfaces 106A, 106B at the upper or exterior surfaces of the bonding layers 118A, 118B can be polished using, for example, chemical mechanical polishing (CMP). The roughness of the polished inorganic bonding surfaces 106A, 106B can be less than 30 Å rms. For example, the roughness of the inorganic bonding surfaces 106A, 106B can be in a range of about 0.5 Å rms to 15 Å rms, 0.5 Å rms to 10 Å rms, or 0.5 Å rms to 5 Å rms. Polishing can also be tuned to leave the conductive features 112 recessed relative to the field regions of the inorganic bonding layer 118B.

Preparation for bonding can also include cleaning and exposing the inorganic bonding surfaces 106A, 106B to a plasma and/or etchants to activate the surfaces 106A, 106B. In some embodiments, the surfaces 106A, 106B can be terminated with a species after activation or during activation (e.g., during the plasma and/or etch processes). Without being limited by theory, in some embodiments, the activation process can be performed to break chemical bonds at the bonding surfaces 106A, 106B, and the termination process can provide additional chemical species at the bonding surfaces 106A, 106B that alter the chemical bond and/or improves the bonding energy between the inorganic bonding surfaces and the respective interface layers 110A, 110B. In some embodiments, the activation and termination are provided in the same step, e.g., a plasma to activate and terminate the surfaces 106A, 106B. In other embodiments, the bonding surfaces 106A, 106B can be terminated in a separate treatment to provide the additional species for bonding. In various embodiments, the terminating species can comprise oxygen. For example, in some embodiments, the inorganic bonding surface(s) 106A, 106B can be exposed to an oxygen-containing plasma. In these embodiments, the inorganic bonding surfaces can be terminated with hydroxyl groups. In some embodiments, the inorganic bonding surface(s) 106A, 106B can be exposed to a water vapor plasma. The roughness of the polished inorganic bonding surfaces 106A, 106B can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

To effectuate bonding between the organic bonding layers 122A, 122B and the corresponding interface layers 110A, 110B, the organic bonding surfaces 108A, 108B of the organic bonding layers 122A, 122B can also be prepared for bonding before the organic bonding layers 122A, 122B are bonded to the interface layers 110A, 110B. The organic bonding surfaces 108A, 108B can be polished using, for example, CMP. The roughness of the polished organic bonding surfaces 108A, 108B can be less than 30 Å rms. For example, the roughness of the organic bonding surfaces 108A, 108B can be in a range of about 0.5 Å rms to 15 Å rms, 0.5 Å rms to 10 Å rms, or 0.5 Å rms to 5 Å rms. Polishing can also be turned to leave the conductive features 114 recessed relative to the field regions of the organic bonding layer 122B. Preparation for bonding can also include cleaning and exposing the organic bonding surfaces to a plasma and/or etchants to activate the surfaces 108A, 108B. In some embodiments, the surfaces 108A, 108B can be terminated with a species to provide additional chemical species at the bonding surfaces 108A, 108B. In various embodiments, the terminating species can comprise oxygen. For example, the organic bonding surfaces 108A, 108B can be exposed to an oxygen-containing plasma to terminate the organic bonding surfaces 108A, 108B with hydroxyl groups. In other embodiments, the organic bonding surfaces 108A, 108B can be terminated with carboxyl groups. As discussed in greater detail elsewhere in the specification, the interface layers 110A, 110B can be formed from a silane coupling agent that has one or more functional groups. Accordingly, in some embodiments, the species that the organic bonding surfaces 108A, 108B is terminated with can depend on the specific functional groups that the silane coupling agent includes.

As discussed in greater detail elsewhere in the specification, the interface layers 110A, 110B are formed by applying a silane coupling agent to the surfaces 106A, 106B of the inorganic bonding layers 118A, 118B. Silane coupling agents are compounds that include two or more functional groups bonded to a central silicon atom. The two or more functional groups, which may also be referred to as functional moieties or ligands, typically include at least one organofunctional group and at least one reactive end group, where the at least one. reactive end group forms a covalent bond with the inorganic bonding surfaces 106A, 106B of the inorganic bonding layers 118A, 118B and the organofunctional group forms a covalent bond with the to the organic bonding surfaces 108A, 108B of the organic bonding layers 122A, 122B. Accordingly, when the silane coupling agent is applied to the inorganic bonding surfaces 106A, 106B, one or more of the reactive end groups in the silane coupling agent can react with and bond to the bonding surfaces 106A, 106B. Similarly, when the bonding surfaces 108A, 108B of the organic bonding layers 122A, 122B contact the respective interface layers 110A, 110B, the functional groups can react with and bond to the bonding surfaces 108A, 108B. In some embodiments, the reactive end groups and functional groups can covalently bond to the bonding surfaces 106A, 106B, 108A, 108B such that the interface layers 110A, 110B are covalently bonded to the bonding surfaces 106A, 106B, 108A, 108B. In some embodiments, the interface layers 110A, 110B can be bonded to the bonding surfaces 106A, 106B, 108A, 108B such that a bond strength between the interface layers 110A, 110B and the inorganic bonding surfaces 106A, 106B is between 1 and 15 J/m², between 1 and 5 J/m², between 5 and 10 J/m², between 10 and 15 J/m², or a value in a range defined by any of these values, and such that a bond strength between the interface layers 110A, 110B and the organic bonding surfaces 108A, 108B is between 1 and 15 J/m², between 1 and 5 J/m², between 5 and 10 J/m², between 10 and 15 J/m², or a value in a range defined by any of these values.

In some embodiments, the inorganic bonding surfaces 106A, 106B define non-conductive field regions and, in some embodiments, the interface layers 110A, 110B are formed over the entire non-conductive field regions. In other embodiments, however, the interface layers 110A, 110B are formed over only a portion of the non-conductive field region. For example, in some embodiments, the interface layers are formed over at least 60% of the non-conductive field region, at least 70% of the non-conductive field region, at least 75% of the non-conductive field region, at least 80% of the non-conductive field region, at least 85% of the non-conductive field region, at least 90% of the non-conductive field region, at least 95% of the non-conductive field region, at least 99% of the non-conductive field region, or a value in a range defined by any of these values. In some embodiments, the interface layers 110A, 110B form a continuous and connected layer such that all portions of the interface layer are connected together. In other embodiments, however, the interface layer can include two or more discrete and disconnected portions. For example, in some embodiments, a first portion a first portion of the interface layer is formed over and bonded to a first portion of the non-conductive field region and a second portion of the interface layer is formed over and bonded to a second portion of the non-conductive field region. In these embodiments, the first and second portions of the non-conductive field region can be disconnected and not overlap with each other such that the first and second portions of the interface layer are disconnected and do not overlap with each other.

However, these reactions can be slow and/or may not go to completion within a reasonable period of time at ambient conditions. Accordingly, in some embodiments, after applying the silane coupling agent to the bonding surfaces 106A, 106B, the silane coupling agent and the first element 102A, 102B can be heated to increase the reaction rate and/or bond strength between the bonding surfaces 106A, 106B and the respective interface layers 110A, 110B. Similarly, after contacting the bonding surfaces 108A, 108B, the bonded structures 100A, 100B can be heated to increase the reaction rate and/or bond strength between the bonding surfaces 108A, 108B and the respective interface layers 110A, 110B. In some embodiments, both heating steps can be performed. In other embodiments, only one of these heating steps may be performed.

The first elements 102A, 102B can be bonded to the second elements 104A, 104B with the interface layers 110A, 110B. In some embodiments, the elements 102A, 102B, 104A, 104B are brought together at room temperature, without the need for application of a voltage, and without the need for application of external pressure or force beyond that used to initiate contact between the two elements. Contact alone can cause bonding between the organic bonding surfaces 122A, 122B and the interface layers 110A, 110B. Subsequent annealing of the bonded structures 100A, 100B can improve the bond strength between the interface layers 110A, 110B and the bonding surfaces 122A, 122B. In embodiments where the bonding layers 118B, 122B include conductive features 112, 114, the subsequent annealing can also cause the conductive features 112, 114 to directly bond.

In various embodiments, prior to bonding, the recesses in the opposing elements can be sized such that the total gap between opposing contact pads is less than 15 nm, or less than 10 nm. In other embodiments, however, the conductive features 112, 114 are not recessed below the bonding surfaces 106B, 108B prior to the first and second elements 102B, 104B being bonded together. Instead, the conductive features 112, 114 can be generally flush with the bonding surfaces 106B, 108B but the presence of the interface layer 110B between the bonding surfaces 106B, 108B causes the surfaces of the conductive features 112, 114 to be spaced apart from each other by approximately the thickness of the interface layer 110B. For example, in some embodiments, the interface layer 110B can have a thickness of 15 nm or less, 10 nm or less, or 5 nm or less and, before bonding, the surfaces of the conductive features 112, 114 can be spaced apart from each other by 15 nm or less, 10 nm or less, or 5 nm or less. Because the recess depths for the conductive features 112, 114 can vary across each element, due to process variation, the noted gap can represent a maximum or an average gap between corresponding conductive features 112, 114 of two joined elements (prior to anneal).

As the conductive features 112, 114 (e.g., metallic material) expands during annealing, the bonds between surrounding non-conductive materials of the inorganic bonding layer 118B and the interface layer 110B and non-conductive materials of the organic bonding layer 122B and the interface layer resist separation of the elements, such that the thermal expansion increases the internal contact pressure between the opposing conductive features. Annealing can also can metallic grain growth across the bonding interface, such that the grains from one element migrate across the bonding interface at least partially into the other element, and vice versa. Thus, in some hybrid bonding elements, opposing conductive materials are joined without being heated above the conductive materials' melting temperature such that bondes can form with lower anneal temperatures compared to soldering or thermocompression bonding. Accordingly, in some embodiments, the bonded structure 100B can be annealed at a temperature of 100° C. to 250° C., 100° C. to 150° C., 150° C. to 200° C., 200° C. to 250° C., 180° C., to 250° C., or a value in a range defined by any of these values.

In various embodiments, the conductive features 112, 114, can comprise discrete pads, contacts, electrodes, or traces at least partially embedded in the non-conductive field regions of the bonding layers 118B, 122B. In some embodiments, the conductive features 112, 114 can comprise exposed contact surfaces of TSVs (e.g., through silicon vias).

As noted above, in some embodiments, prior to bonding, portions of the respective conductive features 112, 114 can be recessed below the non-conductive bonding surfaces 106B and 108B, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 112, 114 or to average depths of the recesses relative to local non-conductive field regions. Even for an individual conductive feature 112, 114, the vertical recess can vary across the feature, and so can be measured at or near the lateral middle or center of the cavity in which a given conductive feature 112, 114 is formed, or can be measured at the sides of the cavity.

Beneficially, the use of hybrid bonding techniques can enable high density of connections between conductive features 112, 114 across the bond interfaces. In some embodiments, a pitch p of the conductive features 112, 114, such as conductive traces embedded in the bonding surface of one of the bonded elements, may be less than 40 μm, less than 20 μm, less than 10 μm, less than 5 μm, less than 2 μm, less than 1 μm, 10 to 20 μm, 5 to 10 am, 2-5 μm, 2-20 μm, 5-20 μm, or a value in a range defined by any of the values. For some applications, the ratio of the pitch of the conductive features 112, 114 to one of the dimensions (e.g., a diameter) of the bonding pad is less than is less than 20, or less than 10, or less than 5, or less than 3 and sometimes desirably less than 2. In various embodiments, the conductive features 112, 114 and/or traces can comprise copper or copper alloys, although other metals may be suitable. For example, the conductive features disclosed herein, such as the conductive features 112, 114, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102B, 104B, as shown, the orientations of one or more conductive features 112, 114 from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initial exposed to the etch. The taper can be even more pronounced when the conductive sidewall is defined directly or indirectly with isotropic wet or dry etching. In the illustrated embodiment, at least one conductive feature 114 in the organic bonding layer 122B (and/or at least one internal conductive feature, such as a BEOL feature) of the second element 104B may be tapered or narrowed upwardly, away from the bonding surface 108B. By way of contrast, at least one conductive feature 112 in the inorganic bonding layer 118B (and/or at least one internal conductive feature, such as a BEOL feature) of the lower element 102B may be tapered or narrowed downwardly, away from the bonding surface 106B. Similarly, any bonding layers (not shown) on the backsides of the elements 102B, 104B may taper or narrow away from the backsides, with an opposite taper orientation relative to front side conductive features 112, 114 of the same element.

As described above, in an anneal phase of hybrid bonding, the conductive features 112, 114 can expand and contact one another to form a metal-to-metal direct bond. In some embodiments, the materials of the conductive features 112, 114 of opposite elements 102B, 104B can interdiffuse during the annealing process. In some embodiments, metal grains grow into each other across the bond interface. In some embodiments, the metal is or includes copper, which can have grains oriented along the 111 crystal plane for improved copper diffusion across the bond interface. In some embodiments, the conductive features 112, 114 may include nanotwinned copper grain structure, which can aid in merging the conductive features during annealing. There is substantially no gap between the non-conductive, inorganic bonding layers 118B and the interface layer 110B, or between the non-conductive organic bonding layer 122B and the interface layer 110B, at or near the bonded conductive features 112, 114. In some embodiments, a barrier layer may be provided under and/or laterally surrounding the conductive features 112, 114 (e.g., which may include copper). In other embodiments, however, there may be no barrier layer under the conductive features 112, 114, for example, as described in U.S. Pat. No. 11,195,748, which is incorporated by reference herein in its entirety and for all purposes.

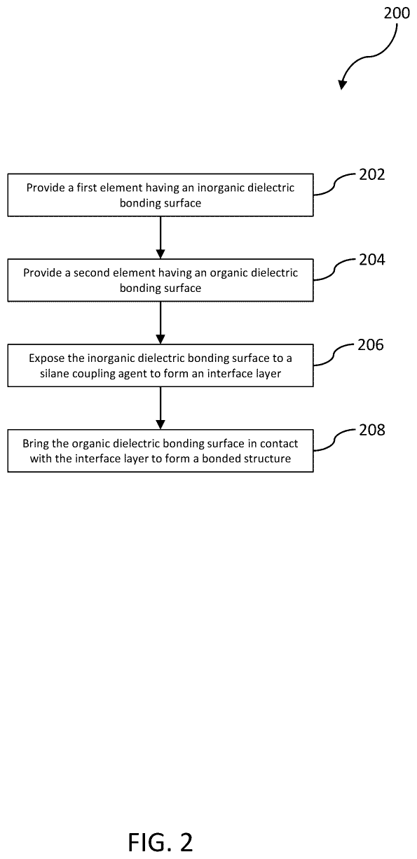

FIG. 2 illustrates a method 200 of forming a bonded structure that includes a first element having an inorganic bonding surface, a second element having an organic bonding surface, and an interface layer between the inorganic bonding surface and the organic bonding surface. At block 202, a first element having an inorganic bonding surface is provided. The inorganic bonding surface can be formed from an inorganic non-conductive material such as an inorganic dielectric material, such as silicon oxide, or an undoped semiconductor material, such as undoped silicon. Suitable inorganic dielectric materials include but are not limited to low K dielectric materials, silicon-containing dielectrics, and/or carbon-containing dielectrics, such as silicon oxide, silicon nitride, silicon oxynitride, silicon carbide, silicon oxycarbonitride, SiCOH dielectrics, silicon carbonitride, diamond-like carbon, and/or a material comprising a diamond surface. Carbon-containing ceramic materials can be considered inorganic, despite the inclusion of carbon. In some embodiments, the first element also includes one or more conductive features formed adjacent to and exposed at the inorganic bonding surface.

At block 204, a second element having an organic bonding surface is provided. The organic bonding surface can be formed from an organic non-conductive dielectric material including polymer materials. Suitable polymer materials include but are not limited to epoxy materials (e.g., epoxy adhesives, cured epoxies, or epoxy composites such as FR-4 materials), liquid crystal polymers, resins, or molding materials. In some embodiments, the polymer material comprises polyimide.

At block 206, the inorganic bonding surface of the first element is exposed to a silane coupling agent to form an interface layer. Silane coupling agents are compounds that include two or more functional groups bonded to a central silicon atom where the two or more functional groups include at least one organofunctional group configured to form strong, covalent bonds with organic materials and at least one alkoxy reactive group configured to form strong, covalent bonds with inorganic materials. The inorganic bonding surface defines a non-conductive field region and, in some embodiments, the entire non-conductive field region is exposed to the silane coupling agent. In other embodiments, however, only a portion of the non-conductive field region is exposed to the silane coupling agent. For example, in some embodiments, the amount of the non-conductive field region that is exposed to the silane coupling agent can be at least at least 60% of the non-conductive field region, at least 70% of the non-conductive field region, at least 75% of the non-conductive field region, at least 80% of the non-conductive field region, at least 85% of the non-conductive field region, at least 90% of the non-conductive field region, at least 95% of the non-conductive field region, at least 99% of the non-conductive field region, or a value in a range defined by any of these values. In some embodiments, a first portion of the non-conductive field region is exposed to a first portion of the silane coupling agent and a second portion of the non-conductive field region is exposed to a second portion of silane coupling agent, where the first and second portions of the non-conductive field region are discontinuous and do not overlap with each other.

In some embodiments, the silane coupling agents can have three alkoxy functional groups and one organofunctional group bonded to a single silicon atom. In these embodiments, the silane coupling agent can have a general structure of (OR)₃—Si—X, where OR represents an alkoxy reactive group (e.g., an oxygen atom O bonded to an alkyl group R) and X represents an organofunctional group. Suitable organofunctional groups include functional groups that form chemical bonds with organic materials (e.g., synthetic resins) and include epoxy groups, amino groups, ureide groups, and isocyanate groups. Other suitable organofunctional groups can include vinyl groups, acryloxy groups, methacryloxy groups, mercapto groups, styryl groups, and carboxylic acid groups. Suitable alkoxy functional groups include reactive groups that form chemical bonds with inorganic materials (e.g., glass, metals, silica) and include methoxy groups and ethoxy groups. In some embodiments, the specific organofunctional and alkoxy functional groups can depend on the specific materials that form the inorganic and organic bonding surfaces. Examples of suitable silane coupling agents include m-aminophenyltrimethoxysilane, aminophenyltrimethoxysilane, (aminoethylaminomethyl) phenethyltrimethoxysilane, 3-glycidoxypropyltrimethoxysila, 3-glycidoxypropyl triethoxysilane, and 2-(3,4-epoxycyclohexyl)ethyltrimethoxysilane. The silane coupling agent can be provided in liquid form and can be applied to the inorganic bonding surface using any suitable technique, including dip coating, spraying, spin coating, stamping with a mold, etc. In some embodiments, the silane coupling agent can be mixed with water and can be provided as an aqueous solution.

When the inorganic bonding surface is exposed to the silane coupling agent, the alkoxy reactive groups in the silane coupling agent can undergo a hydrolysis reaction whereby the alkoxy reactive groups attached to the central silicon atom are replaced by hydroxyl groups. During the hydrolysis reaction, water molecules within the aqueous solution cause the bond between the central silicon atom and the alkoxy reactive groups to break. Hydrogen ions (H⁺) from the water molecules bond to the oxygen atom of the negatively-charged alkoxy group to form methoxy and ethoxy molecules. Simultaneously, the remaining hydroxyl ions (OH⁻) from the water molecules bond to the central silicon atom, replacing the alkoxy reactive groups. The resulting hydrolyzed silane coupling agent form a silanol compound that includes the central silicon atom, the one or more organofunctional groups bonded to the central silicon atom, and the one or more hydroxyl groups bonded to the central silicon. In embodiments where the silane coupling agent includes three alkoxy functional groups and one organofunctional group, this process can occur according to the following reaction:

Si(OR)₃X+3H₂O→Si(OH)₃X+HOR

After the alkoxy functional groups undergo the hydrolysis reaction, the hydrolyzed silane coupling agent compounds in the solution can bond together via a condensation reaction to form oligomers. In a condensation reaction, a hydroxyl group bonded to one of the central silicon atoms can react with a hydroxyl group bonded to another central silicon atom, resulting in the two central silicon atoms being bonded together (via an oxygen atom) and a water molecule being released, as shown in the following reaction:

Si(OH)₃X+Si(OH)₃X→X(OH)₂Si—O—Si(OH)₂X+H₂O

While these condensation reactions proceed and the oligomers grow, some of the hydroxyl groups can bond to the inorganic bonding surface of the first element. As described in greater detail elsewhere in the specification, prior to exposing the inorganic bonding surface to the silane coupling agent, the inorganic bonding surface can be exposed to an oxygen plasma and terminated with hydroxyl groups. When hydroxyl groups from the hydrolyzed silane coupling agent interact with the hydroxyl groups on the inorganic bonding surface, the hydroxyl groups can bond together via hydrogen bonding. This process results in the oligomers being hydrogen bonded to the inorganic bonding surface of the first element. However, these processes can be slow and may not go to completion at ambient conditions or may not go to completion in a reasonable amount of time. Additionally, hydrogen bonds are comparatively weak bonds.

Accordingly, as discussed in greater detail elsewhere in the specification, the first element and the hydrogen-bonded interface layer formed on the first element can be heated. For example, in some embodiments, the first element and the hydrogen-bonded interface layer can be heated at a temperature of 120° C. for 30 to 90 minutes. In other embodiments, the first element and the hydrogen-bonded interface layer can be heated at a temperature between 80° C. and 180° C., 100° C. and 150° C., 110° C. and 130° C., 80° C. and 130° C., 110° C. and 180° C., 80° C. and 120° C., 120° C. and 180° C., or a value in a ranged defined by any of these values, and can be heated for 20 to 120 minutes, 30 to 90 minutes, 40 to 80 minutes, 50 to 60 minutes, 30 to 60 minutes, 60 to 120 minutes, or a value in a range defined by any of these values. Heating the interface layer can increase the hydrolysis, condensation, and hydrogen bonding reaction rates to ensure that these reactions go to completion in a reasonable amount of time. Additionally, heating the hydrogen bonded silanol oligomers can cause the silanol to undergo a dehydration condensation reaction that results in the formation of the silicon atoms being covalently bonded to the inorganic bonding surface of the first element, via an oxygen atom. During the dehydration condensation reaction, a water molecule is released and the heat can cause the water molecule to evaporate while the silicon and oxygen atoms remain bonded to the first element. The heat can also cause other molecules (e.g., methanol and ethanol molecules from the initial hydrolysis reaction and water molecules from the initial condensation reaction) to evaporate. Accordingly, exposing the inorganic bonding surface to the silane coupling agent and then heating the silane coupling agent results in the formation of an interface layer that is covalently bonded to the inorganic bonding surface and that still has the organofunctional groups still being bonded to the silicon atoms.

At block 208, the organic bonding surface of the second element is brought into contact with the interface layer to form a bonded structure. When the organic bonding surface contacts the interface layer, the organofunctional groups in the interface layer can react with the organic bonding surface to bond the organic bonding layer to the interface layer. In some embodiments, the organofunctional groups are configured to react with specific chemical species. In these embodiments, as described in greater detail elsewhere in the specification, the organic bonding surface can be terminated with chemical species prior to the organic bonding surface contacting the interface layer. For example, in some embodiments, the organofunctional groups can be epoxide groups that are configured to react with hydroxyl groups and the organic bonding surface can be terminated with hydroxyl groups by exposing the organic bonding surface to oxygen plasma. In these embodiments, the epoxide groups can react with the hydroxyl groups via an epoxide ring opening reaction. In some embodiments, the organofunctional group can be configured to react with more than one chemical species. For example, in some embodiments, the epoxide groups can react with hydroxyl groups, carboxyl groups, or amine groups. In some embodiments, the organofunctional group can be configured to react with the chemical species via different types of reactions, depending on the specific chemical species. For example, while the epoxide groups can react with hydroxyl and carboxyl groups via epoxide ring opening reactions, the epoxide groups can react with amine groups via a different chemical reaction. Specifically, when the epoxide group reacts with an amine group, an active hydrogen atom in the amine reacts with the epoxide group to form a secondary amine. The secondary amine can then bond with another epoxide group, thereby curing the two epoxide groups and forming a tertiary amine. The resulting tertiary amine can function as a polymerization catalyst for other epoxide groups that facilitates curing of the epoxide groups. Other organofunctional groups can be configured to react with the same or different reactive groups via the same or different types of reactions. In still other embodiments, the organofunctional group can be configured to react with the organic dielectric material directly. In these embodiments, the organic bonding surface may not be terminated with an active group prior to the organic bonding surface contacting the interface layer.

In some embodiments, after forming the interface layer over the inorganic bonding surface but before contacting the interface layer with the organic bonding surface, the interface layer can be exposed to one or more cleaning solutions. In some embodiments, the organofunctional groups can undesirably and prematurely react when exposed to compounds in the cleaning solution, which can render the organofunctional groups unable to bond to organic bonding surface. In these embodiments, care must be taken to ensure that the organofunctional groups are selected such that they do not react with cleaning solutions. For example, as discussed in greater detail elsewhere in the specification, in some embodiments, tetramethyl ammonium hydroxide (TMAH) is used to strip a photoresist from the inorganic bonding surface after forming the interface layer. However, TMAH cleaning solutions are very basic and epoxide organofunctional groups undergo a ring opening reaction in basic conditions. Accordingly, in embodiments where the interface layer is exposed to TMAH prior to the organic bonding surface contacting the interface layer, the silane coupling agent can have an organofunctional group that does not react in basic conditions, such as an amine organofunctional group.

When the organic bonding surface contacts the interface layer, the organofunctional groups can react with the organic bonding surface (or reactive groups terminated on the on the organic bonding surface) to form covalent bonds between the interface layer and the organic bonding surface. However, in some embodiments, these reactions can be slow under ambient conditions. Accordingly, in some embodiments, after contacting the organic bonding surface to the interface layer, the second element and the interface layer can be heated to increase the reaction rate. In some embodiments, pressure can also be applied to a back surface of the second element (i.e., the opposite side of the second element from the organic bonding surface) to ensure good contact between the organic bonding surface and the interface layer.

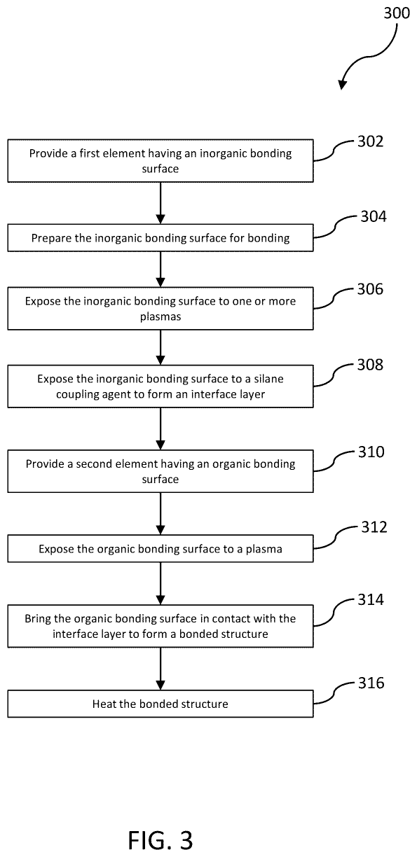

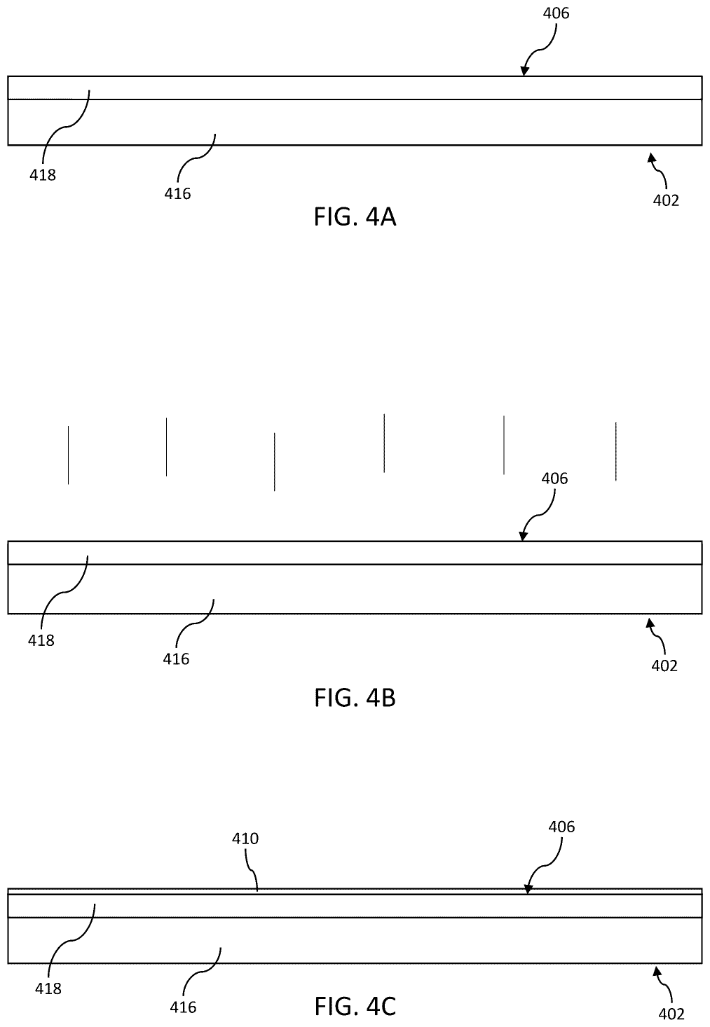

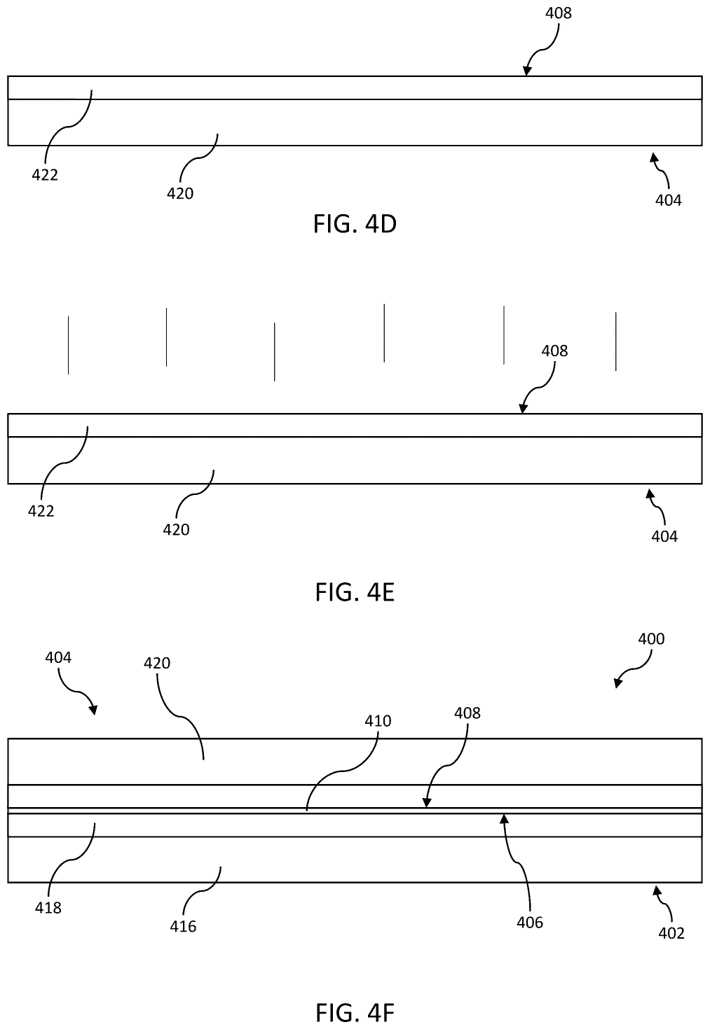

FIG. 3 is a flowchart illustrating a process 300 for bonding a first element having an inorganic bonding surface to a second element having an organic bonding surface using an interface layer formed from a silane coupling agent. FIGS. 4A-4F are schematic side sectional views of microelectronic elements at various blocks of the process 300 shown in FIG. 3.

As shown in FIG. 4A, at block 302, a first element 402 having an inorganic bonding surface 406 is provided. The first element 402, which may be generally similar to the first element 102A shown and described above in connection with FIG. 1A, has a base substrate portion 416 and an inorganic bonding layer 418 formed on the base substrate portion 416, where the inorganic bonding layer 418 forms the inorganic bonding surface 406. The inorganic bonding layer 418 can be formed from an inorganic non-conductive material such as an inorganic dielectric material, such as silicon oxide, or an undoped semiconductor material, such as undoped silicon. Suitable inorganic dielectric materials include but are not limited to low K dielectric materials, silicon-containing dielectric materials, and/or carbon-containing dielectric materials, such as silicon oxide, silicon nitride, silicon oxynitride, silicon carbide, silicon oxycarbonitride, SiCOH dielectrics, silicon carbonitride, diamond-like carbon, and/or a material comprising a diamond surface. Carbon-containing ceramic materials can be considered inorganic, despite the inclusion of carbon. The base substrate portion 416 can comprise a device portion, such as a bulk semiconductor (e.g., silicon) portion of the first element 402 or BEOL interconnect layers over such semiconductor portions. Active devices and/or circuitry can be patterned and/or otherwise disposed in or on the base substrate portion 416. Active devices and/or circuitry can be disposed at or near the front sides of the base substrate portion 416 (e.g., at or near the inorganic bonding layer 418) and/or at or near opposite back sides of the base substrate portion 416 (e.g., at or near the surface of the first element 402 that opposes the inorganic bonding surface 406. In other embodiments, the base substrate portion 416 may not include active circuitry, but may instead comprise dummy substrates, interposers, passive optical elements (e.g., glass substrates, gratings, lenses), etc.

At block 304, the inorganic bonding surface 406 is prepared for bonding. In some embodiments, the inorganic bonding surface 406 can be prepared for bonding by planarizing and/or polishing. In some embodiments, the inorganic bonding surface 406 can be planarized by grinding the inorganic bonding surface until it is flat and/or smooth. In some embodiments, the inorganic bonding surface 406 can be polished to a high degree of smoothness (e.g., by CMP) until the inorganic bonding surface 406 has a surface roughness of less than 30 Å rms. For example, the roughness of the inorganic bonding surface 406 can be in a range of about 0.5 Å rms to 15 Å rms, 0.5 Å rms to 10 Å rms, 0.5 Å rms to 5 Å rms, or a value in a range defined by any of these ranges.

As shown in FIG. 4B, at block 306, the inorganic bonding surface 406 is exposed to one or more plasmas to activate and/or terminate the inorganic bonding surface 406. As described above in connection with FIGS. 1A and 1B, the activation process can be performed to break chemical bonds at the inorganic bonding surface bonding surface 406 and the termination process can provide additional chemical species at the bonding surface that alters the chemical bond and/or improves the bonding energy between the inorganic bonding surface 406 and an interface layer formed on the inorganic bonding surface. In some embodiments, the inorganic bonding surface 406 is exposed to an oxygen plasma to activate the inorganic bonding surface 406 and terminate the inorganic bonding surface with hydroxyl groups that bond to the alkoxy reactive groups in the silane coupling agent that forms the interface layer. In some embodiments, the inorganic bonding surface can be exposed to more than one type of plasma. For example, in some embodiments, the inorganic bonding surface 406 can be exposed to a first plasma to activate the inorganic bonding surface 406 and then exposed to a second plasma to terminate the inorganic bonding surface with reactive species. For example, in some embodiments, the inorganic bonding surface 406 is first exposed to a nitrogen plasma to activate the inorganic bonding surface 406 and then the inorganic bonding surface 406 is exposed to an oxygen plasma to terminate the inorganic bonding surface with hydroxyl groups.

As shown in FIG. 4C, at block 308, the inorganic bonding surface 406 is exposed to a silane coupling agent to form an interface layer 410 on the inorganic bonding surface 406. As described above in connection with FIG. 2, silane coupling agents are compounds that include at least one alkoxy reactive group and at least one organofunctional group that are each bonded to a central silicon atom. The one or more alkoxy reactive groups can include methoxy and ethoxy groups and the one or more organofunctional groups can include vinyl groups, epoxy groups, amino groups, acryloxy groups, methacryloxy groups, mercapto groups, styryl groups, ureide groups, and isocyanate groups. The silane coupling agent can be provided in liquid form (e.g., in an aqueous solution) and can be applied to the inorganic bonding surface 406 using any suitable technique, including die coating, spraying spin coating, or stamping. When the inorganic bonding surface 406 is exposed to the silane coupling agent, the alkoxy reactive groups in the silane coupling agent can undergo hydrolysis and condensation reactions to form silanol oligomers. The silanol oligomers can weakly bond to the terminated inorganic bonding surface 406 (e.g., via hydrogen bonding between hydroxyl groups on the inorganic bonding surface and the silanol oligomers) before undergoing a dehydration condensation reaction that results in the formation of the interface layer 410 being covalently bonded to the inorganic bonding surface 406. In some embodiments, after the interface layer 410 is formed on the inorganic bonding surface 406, the interface layer 410 can have a thickness of 3 to 5 nanometers (nm). In other embodiments, however, the interface layer 410 can have a different thickness. For example, in some embodiments, the interface layer 410 can have a thickness of 20 nm or less, 15 nm or less, 10 nm or less, 5 nm or less, 1 to 20 nm, 3 to 15 nm, 5 to 10 nm, 3 to 5 nm, 10 to 15 nm, 15 to 20 nm, or a thickness in a range defined by any of these values. In some embodiments, the interface layer 410 can comprise a single monolayer of silanol. In other embodiments, the interface layer 410 can comprise two or more layers of silanol.

In some embodiments, after applying the silane coupling agent to the inorganic bonding surface 406, the first element 402 and the interface layer 410 are heated to increase the reaction rate of the hydrolysis reactions, condensation reactions, and hydrogen bonding, and also to cause the hydrogen-bonded silanol oligomers to undergo the dehydration condensation reaction. Heating the first element 402 and the interface layer 410 can also cause compounds mixed with the silanol oligomers (e.g., water, methanol, and ethanol molecules) to evaporate. In some embodiments, the first element 402 and interface layer 410 are heated to 120° C. for 30 to 90 minutes. In other embodiments, the first element 402 and interface layer 410 are heated to a different temperature for a different amount of time. For example, in some embodiments, the first element 402 and interface layer 410 are heated to a temperature between 100° C. and 150° C., between 110° C. and 140° C., between 120° C. and 130° C., between 100° C. and 120° C., between 120° C. and 150° C., between 110° C. and 130° C., or a temperature in a range defined by any of these values, and the first element 402 and the interface layer 410 are heated for 20 to 120 minutes, 30 to 90 minutes, 40 to 80 minutes, 50 to 70 minutes, 30 to 60 minutes, 60 to 90 minutes, or a time in a range defined by any of these values.

As shown in FIG. 4D, at block 310, a second element 404 having an organic bonding surface 408 is provided. The second element 404, which may be generally similar to the second element 104A shown and described in connection with FIG. 1A, has a base substrate portion 420 and an organic bonding layer 422 formed on the base substrate portion 420, where the organic bonding layer 422 forms the organic bonding surface 408. The organic bonding layer 422 can be formed from an organic dielectric material, such as a polymer materials. Suitable polymer materials include epoxies (e.g., epoxy adhesives, cured epoxies, or epoxy composites such as FR-4 materials), resins, or molding materials. In some embodiments, the organic bonding layer 422 comprises polyimide.

In some embodiments, the organic bonding surface 408 can be prepared for bonding. For example, in some embodiments, the organic bonding surface 408 can be planarized and or polished until the organic bonding surface 408 is flat and/or smooth. In other embodiments, however, the organic bonding surface 408 may not be planarized or polished.

As shown in FIG. 4E, at block 312, the organic bonding surface 408 is exposed to oxygen plasma to terminate the organic bonding surface 408 with additional chemical species that the organofunctional groups of the silane coupling agent can bond to. For example, in some embodiments, the organic bonding surface 408 is exposed to an oxygen plasma to terminate the organic bonding surface 408 with hydroxyl groups. In other embodiments, the organic bonding surface 408 can be exposed to a plasma other than oxygen plasma and the organic bonding surface 408 can be terminated with other species besides hydroxyl groups.

In the illustrated embodiment, the organic bonding surface 408 is terminated with the chemical species by exposing the organic bonding surface 408 to a plasma. In other embodiments, however, the organic bonding surface 408 can be terminated with chemical species without exposing the organic bonding surface to plasma. For example, in some embodiments, the organic bonding surface 408 can be terminated with carboxyl groups by exposing the organic bonding surface 408 to carboxylic acid. In still other embodiments, the organic bonding surface 408 may not be terminated with chemical species prior to bonding the organic bonding surface 408 to the interface layer 410. For example, in some embodiments, silane coupling agent can include an organofunctional group that can covalently bond to the organic dielectric material that the organic bonding layer 422 is formed from.

As shown in FIG. 4F, at block 314, the organic bonding surface 408 is brought into contact with the interface layer 410 to form the bonded structure 400. As described above in connection with FIG. 2, when the organic bonding surface 408 contacts the interface layer 410, the organofunctional groups in the interface layer 410 can react with the organic bonding surface 408. For example, in some embodiments, the organofunctional groups can comprise epoxy groups and contacting the organic bonding surface 408 to the interface layer 410 can cause the epoxide groups to undergo an epoxy ring opening reaction that results in the interface layer 410 being covalently bonded to the organic bonding layer 422.

In some embodiments, the organic bonding surface 408 is brought into contact with the interface layer 410 to form the bonded structure 400 without applying any additional pressure (e.g., without applying any additional pressure beyond what is necessary to bring the organic bonding surface 408 in contact with the interface layer 410). In these embodiments, after contacting the organic bonding surface to the interface layer 410, no additional pressure may be applied to the second element 404 to facilitate bonding between the organic bonding surface 408 and the interface layer 410. In other embodiments, however, pressure can be applied to the second element 404 after the organic bonding surface 408 contacts the interface layer 410. For example, in some embodiments, pressure can be applied to the back side of the second element 404 (e.g., the surface of the second element 404 defined by the base substrate portion 420 and that opposes the organic bonding surface 408) after the organic bonding surface 408 contacts the interface layer 410 so as to facilitate bonding and improve bond strength between organic bonding surface 408 and the interface layer 410.

As described above in connection with FIG. 2, at block 316, the bonded structure 400 is heated to increase the rate at which the organofunctional groups bond to the organic bonding surface 408. In some embodiments, the bonded structure 400 is heated at a temperature of 180° C. for 1.5 hours. In other embodiments, the bonded structure 400 is heated at a different temperature for a different amount of time. For example, in some embodiments, the bonded structure 400 is heated at a temperature of 100° C. to 250° C., 100° C. to 150° C., 150° C. to 200° C., 200° C. to 250° C., 150° C. to 250° C., 180° C. to 250° C., or a value in a range defined by any of these values, and is heated for 1 to 2 hours, 1 to 1.5 hours, 1.5 to 2 hours, 1.25 to 1.75, or a value in a range defined by any of these values. In some embodiments, heating the bonded structure 400 comprises annealing the bonded structure 400 to increase the bonding strength between the interface layer 410 and the organic bonding surface 408.

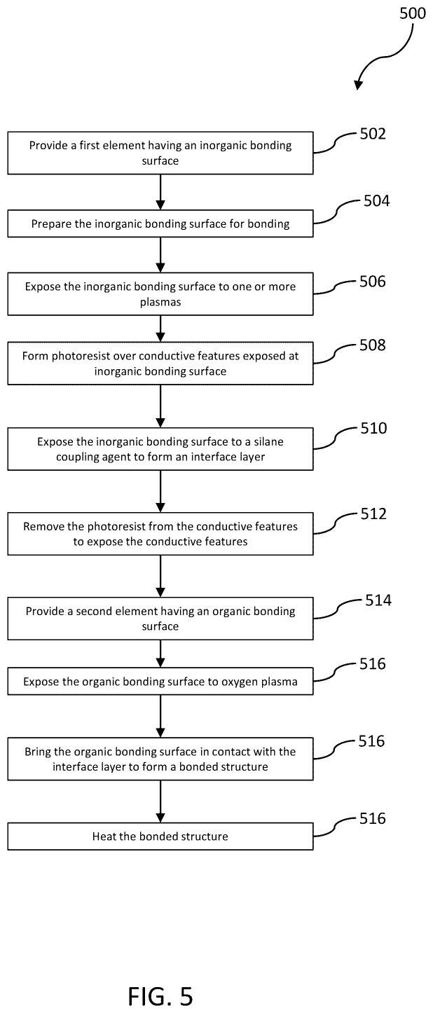

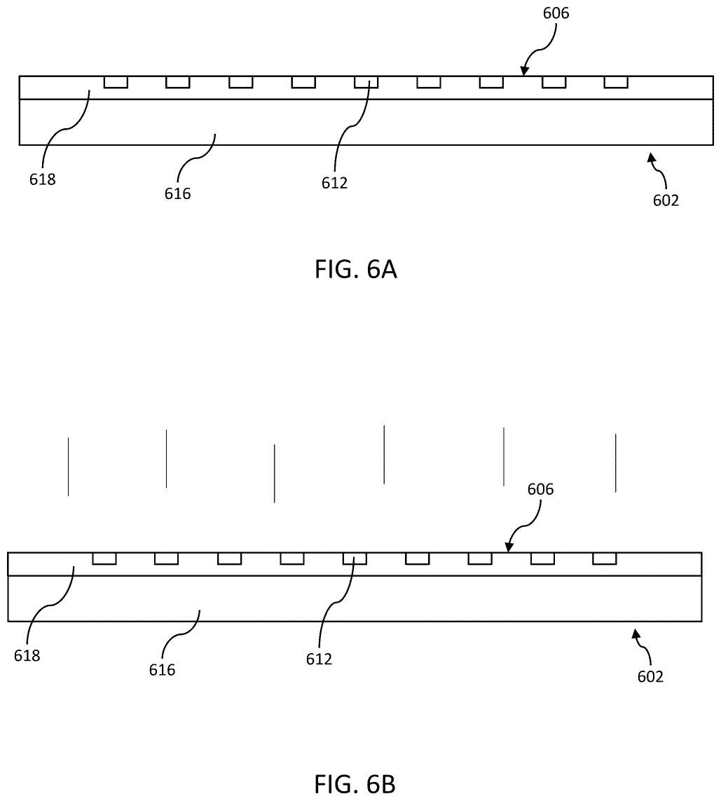

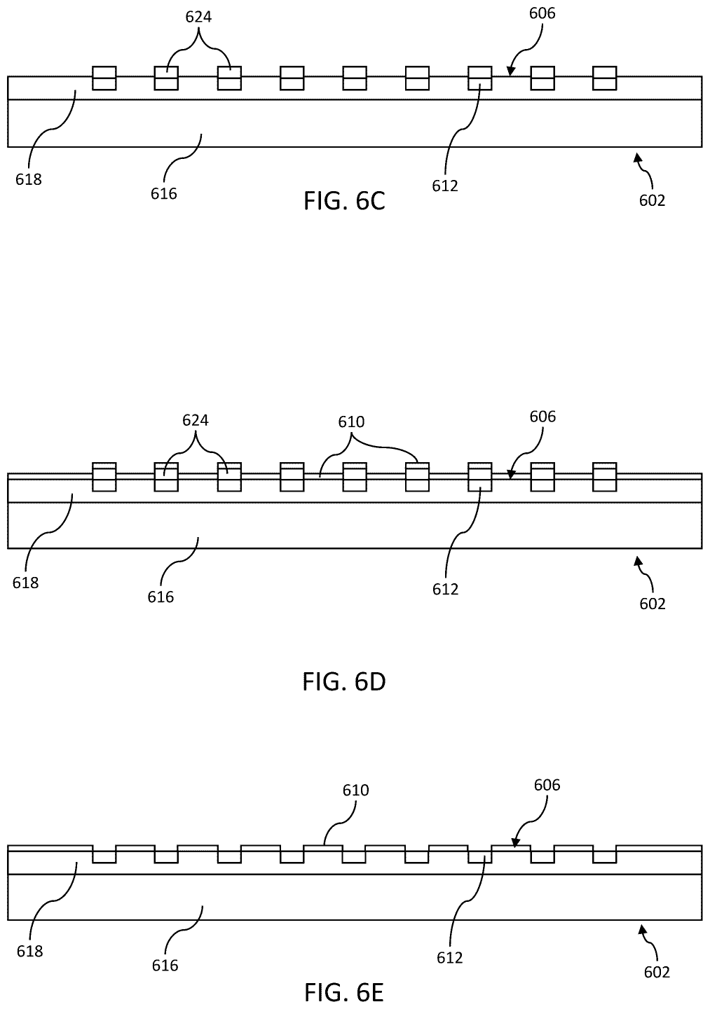

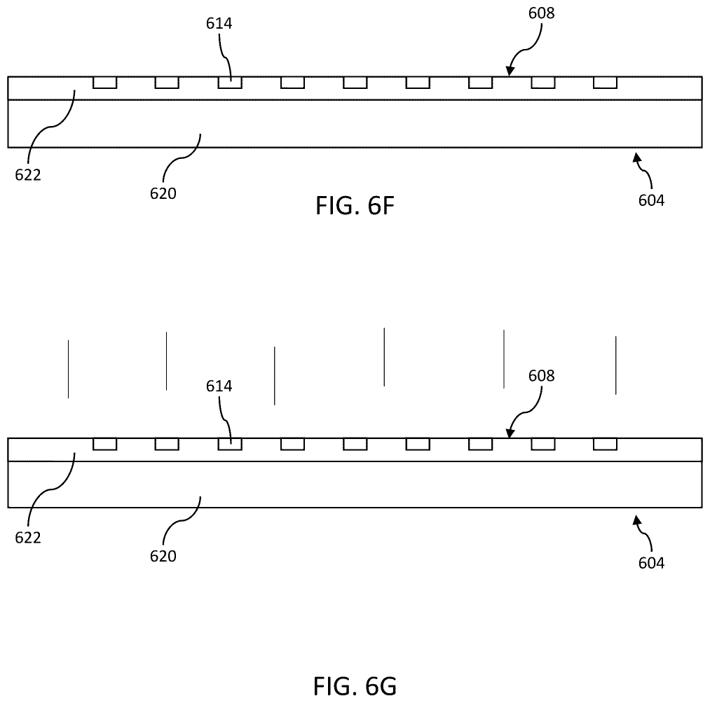

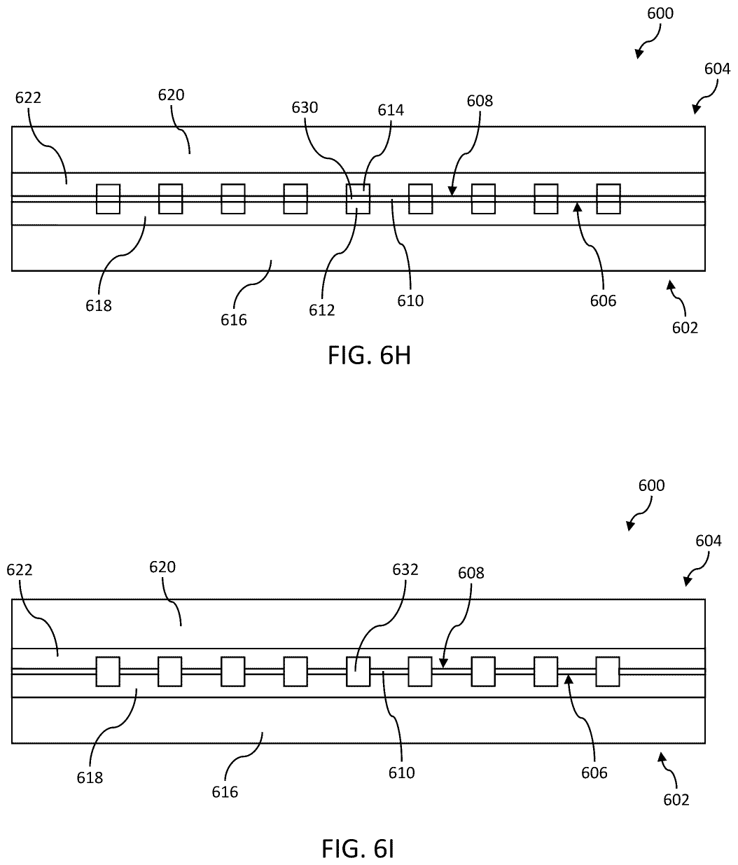

FIG. 5 is a flowchart illustrating a process 500 for bonding a first element having an in inorganic bonding surface and one or more conductive features formed at the inorganic bonding surface to a second element having an organic bonding surface and one or more conductive features formed at the organic bonding surface using an interface layer formed from a silane coupling agent. FIGS. 6A-6I are schematic side sectional views of microelectronic elements at various blocks of the process 500 shown in FIG. 5.

As shown in FIG. 6A, at block 502, a first element 602 having an inorganic bonding surface 606 is provided. The first element 602, which may be generally similar to the first element 102B shown and described above in connection with FIG. 1B, has a base substrate portion 616 and an inorganic bonding layer 618 formed on the base substrate portion 616, where the inorganic bonding layer 618 forms the inorganic bonding surface 606. The first element 602 also includes one or more conductive features 612 formed in the inorganic bonding layer 618 and exposed at the inorganic bonding surface 606.

The inorganic bonding layer 618 can be formed from an inorganic non-conductive material such as an inorganic dielectric material, such as silicon oxide, or an undoped semiconductor material, such as undoped silicon. Suitable inorganic dielectric materials include but are not limited to low K dielectric materials, silicon-containing dielectric materials, and/or carbon-containing dielectric materials, such as silicon oxide, silicon nitride, silicon oxynitride, silicon carbide, silicon oxycarbonitride, SiCOH dielectrics, silicon carbonitride, diamond-like carbon, and/or a material comprising a diamond surface. Carbon-containing ceramic materials can be considered inorganic, despite the inclusion of carbon. The base substrate portion 616 can comprise a device portion, such as a bulk semiconductor (e.g., silicon) portion of the first element 602 or BEOL interconnect layers over such semiconductor portions. Active devices and/or circuitry can be patterned and/or otherwise disposed in or on the base substrate portion 616. Active devices and/or circuitry can be disposed at or near the front sides of the base substrate portion 616 (e.g., at or near the inorganic bonding layer 618) and/or at or near opposite back sides of the base substrate portion 616 (e.g., at or near the surface of the first element 602 that opposes the inorganic bonding surface 606. In other embodiments, the base substrate portion 616 may not include active circuitry, but may instead comprise dummy substrates, interposers, passive optical elements (e.g., glass substrates, gratings, lenses), etc.

The conductive features 612, which can be generally similar to the conductive features 112 shown in FIG. 1B, can include contact pads, traces, electrodes, exposed ends of vias, or through substrate features. In some embodiments, one or more of the conductive features 612 can be electrically connected to active devices and/or circuitry within the base substrate portion 616. In various embodiments, the conductive features 612 can comprise discrete pads or traces at least partially embedded in the inorganic bonding layer 618, which forms non-conductive field regions. In some embodiments, the conductive contact features can comprise exposed contact surfaces of through substrate vias (e.g., through silicon vias (TSVs)). In some embodiments, prior to dielectric bonding, portions of the conductive features 612 can be recessed below the non-conductive bonding surfaces 606) of the dielectric field region or non-conductive bonding layers 618. For example, in some embodiments, portions of the conductive features 612 can be recessed by less than 10 nm, less than 8 nm, less than 5 nm, or less than 3 nm, for example, recessed in a range of 0 nm to 10 nm, or in a range of 2 nm to 5 nm. In some embodiments, the recess can be formed by polishing the inorganic bonding layer 618. In some embodiments, the recess of some or all of the conductive features 612 can be selectively increased by etching some or all of the conductive features 612 (e.g., by applying a dilute wet etchant). The recess can be at or near the middle or center of the cavity in which the conductive features 612 are disposed, and, additionally or alternatively, can extend or be disposed along sides of the cavity in which the conductive features 612 are disposed. In other embodiments, however, the conductive features 612 are not recessed below the inorganic bonding surface 606. Instead, the conductive features 612 can be generally flush with the inorganic bonding surface 606.

At block 504, the inorganic bonding surface 606 is prepared for bonding. In some embodiments, the inorganic bonding surface 606 can be prepared for bonding by planarizing and/or polishing. In some embodiments, the inorganic bonding surface 606 can be planarized by grinding the inorganic bonding surface until it is flat and/or smooth. In some embodiments, the inorganic bonding surface 606 can be polished to a high degree of smoothness (e.g., by CMP) until the inorganic bonding surface 606 has a surface roughness of less than 30 Å rms. For example, the roughness of the inorganic bonding surface 606 can be in a range of about 0.5 Å rms to 15 Å rms, 0.5 Å rms to 10 Å rms, 0.5 Å rms to 5 Å rms, or a value in a range defined by any of these ranges.

As shown in FIG. 6B, at block 506, the inorganic bonding surface 606 is exposed to one or more plasmas to activate and/or terminate the inorganic bonding surface 606. As described above in connection with FIGS. 1A and 1B, the activation process can be performed to break chemical bonds at the inorganic bonding surface bonding surface 606 and the termination process can provide additional chemical species at the bonding surface that alters the chemical bond and/or improves the bonding energy between the inorganic bonding surface 606 and an interface layer formed on the inorganic bonding surface. In some embodiments, the inorganic bonding surface 606 is exposed to an oxygen plasma to activate the inorganic bonding surface 606 and terminate the inorganic bonding surface with hydroxyl groups that bond to the alkoxy reactive groups in the silane coupling agent that forms the interface layer. In some embodiments, the inorganic bonding surface can be exposed to more than one type of plasma. For example, in some embodiments, the inorganic bonding surface 606 can be exposed to a first plasma to activate the inorganic bonding surface 606 and then exposed to a second plasma to terminate the inorganic bonding surface with reactive species. For example, in some embodiments, the inorganic bonding surface 606 is first exposed to a nitrogen plasma to activate the inorganic bonding surface 606 and then the inorganic bonding surface 606 is exposed to an oxygen plasma to terminate the inorganic bonding surface with hydroxyl groups.

As shown in FIG. 6C, at block 508, a photoresist 624 is formed over the conductive features 612 that are exposed at the inorganic bonding surface 606. In some embodiments, the photoresist 624 is formed using lithographic techniques. For example, in some embodiments, the photoresist 624 is formed by depositing the photoresist material over the entire inorganic bonding surface 606 and the conductive features 612 and then patterning the photoresist material to remove the portions of the photoresist material that are over the inorganic bonding surface 606 without removing the portions of the photoresist material that are over the conductive features 612. In this way, the photoresist 624 can be formed such that it covers conductive features 612 but does not cover the inorganic bonding surface 606. In some embodiments, after forming the photoresist 624 over the conductive features 612, the uncovered inorganic bonding surface 606 can be cleaned by, for example, exposing the inorganic bonding surface 606 to one or more cleaning agents, such as deionized water or alcohol.

As shown in FIG. 6D, at block 510, the inorganic bonding surface 606 is exposed to a silane coupling agent to form an interface layer 610. As described above in connection with FIG. 2, silane coupling agents are compounds that include at least one alkoxy reactive group and at least one organofunctional group that are each bonded to a central silicon atom. The one or more alkoxy reactive groups can include methoxy and ethoxy groups and the one or more organofunctional groups can include vinyl groups, epoxy groups, amino groups, acryloxy groups, methacryloxy groups, mercapto groups, styryl groups, ureide groups, and isocyanate groups. The silane coupling agent can be provided in liquid form (e.g., in an aqueous solution) and can be applied to the inorganic bonding surface 606 using any suitable technique, including die coating, spraying spin coating, or stamping. When the inorganic bonding surface 606 is exposed to the silane coupling agent, the alkoxy reactive groups in the silane coupling agent can undergo hydrolysis and condensation reactions to form silanol oligomers. The silanol oligomers can weakly bond to the terminated inorganic bonding surface 606 (e.g., via hydrogen bonding between hydroxyl groups on the inorganic bonding surface and the silanol oligomers) before undergoing a dehydration condensation reaction that results in the formation of the interface layer 610 being covalently bonded to the inorganic bonding surface 606. In some embodiments, after the interface layer 610 is formed on the inorganic bonding surface 606, the interface layer 610 can have a thickness of 3 to 5 nanometers (nm). In other embodiments, however, the interface layer 610 can have a different thickness. For example, in some embodiments, the interface layer 610 can have a thickness of 15 nm or less, 10 nm or less, 5 nm or less, 1 to 15 nm, 3 to 12 nm, 5 to 10 nm, 3 to 5 nm, 10 to 15 nm, or a thickness in a range defined by any of these values. In some embodiments, the interface layer 610 can comprise a single monolayer of silanol. In other embodiments, the interface layer 610 can comprise two or more layers of silanol.

When the silane coupling agent is applied to first element 602, the photoresist 624 prevents the silane coupling agent from contacting the conductive features 612. Accordingly, in some embodiments, only the non-conductive field region of the inorganic bonding surface 606 is exposed to the silane coupling agent while the surface of the conductive features 612 is not exposed to the silane coupling agent. In these embodiments, the interface layer 610 is only formed over the non-conductive field region of the inorganic bonding surface 606. In some embodiments, some of the silane coupling agent can form a layer 626 on the top surface of the photoresists 624.

In some embodiments, after applying the silane coupling agent to the inorganic bonding surface 606, the first element 602 and the interface layer 610 are heated to increase the reaction rate of the hydrolysis reactions, condensation reactions, and hydrogen bonding, and also to cause the hydrogen-bonded silanol oligomers to undergo the dehydration condensation reaction. Heating the first element 602 and the interface layer 610 can also cause compounds mixed with the silanol oligomers (e.g., water, methanol, and ethanol molecules) to evaporate. In some embodiments, the first element 602 and interface layer 610 are heated to 120° C. for 30 to 90 minutes. In other embodiments, the first element 602 and interface layer 610 are heated to a different temperature for a different amount of time. For example, in some embodiments, the first element 602 and interface layer 610 are heated to a temperature between 100° C. and 150° C., between 110° C. and 140° C., between 120° C. and 130° C., between 100° C. and 120° C., between 120° C. and 150° C., between 110° C. and 130° C., or a temperature in a range defined by any of these values, and the first element 602 and the interface layer 610 are heated for 20 to 120 minutes, 30 to 90 minutes, 40 to 80 minutes, 50 to 70 minutes, 30 to 60 minutes, 60 to 90 minutes, or a time in a range defined by any of these values.

As shown in FIG. 6E, at block 512, the photoresist 624 is removed from the first element 602 to expose the conductive features 612. After removing the photoresist 624, the first element 602 includes the interface layer 610 formed on the inorganic bonding surface 606 while the conductive features 612 are exposed and not covered by the interface layer 610.

The photoresist 624 can be removed from the first element using any suitable photoresist stripping technique, including by exposing the photoresist 624 to TMAH or an organic solvent. However, care must be taken to ensure that the photoresist stripping process does not react with the organofunctional groups in the interface layer 610 and cause the organofunctional groups to undergo a chemical reaction that prevents or inhibits the interface layer 610 from bonding with the organic bonding surface. For example, in some embodiments, tetramethyl ammonium hydroxide (TMAH) is used to strip the photoresist 624. However, TMAH is a basic compound and organofunctional groups that include epoxide groups undergo a ring opening reaction under basic conditions, which means that using TMAH as a photoresist in embodiments where the organofunctional group is an epoxy group can result in the interface layer 610 unable to form a strong bond with the organic bonding surface of the second element. Accordingly, in embodiments where the silane coupling agent includes an epoxide organofunctional group, a photoresist stripping process that does not include TMAH should be used to remove the photoresist 624. Conversely, in embodiments where TMAH is to be used to remove the photoresist 624, the silane coupling agent can include an organofunctional group that does not react under basic conditions, such as an amine organofunctional group. In some embodiments, after removing the photoresist 624, the conductive features 612 can be cleaned by, for example, exposing the conductive features 612 to one or more cleaning agents, such as deionized water and/or alcohol.

As shown in FIG. 6F, at block 514, a second element 604 having an organic bonding surface 608 is provided. The second element 604, which may be generally similar to the second element 104B shown and described in connection with FIG. 1B, has a base substrate portion 620 and an organic bonding layer 622 formed on the base substrate portion 620, where the organic bonding layer 622 forms the organic bonding surface 608. The second element 604 also includes one or more conductive features 614 formed in the organic bonding layer 622 and exposed at the organic bonding surface 608. The organic bonding layer 622 can be formed from an organic dielectric material, such as a polymer materials. Suitable polymer materials include epoxies (e.g., epoxy adhesives, cured epoxies, or epoxy composites such as FR-4 materials), resins, or molding materials. In some embodiments, the organic bonding layer 622 comprises polyimide.

The conductive features 614, which can be generally similar to the conductive features 114 shown in FIG. 1B, can include contact pads, traces, electrodes, exposed ends of vias, or through substrate features. In some embodiments, one or more of the conductive features 614 can be electrically connected to active devices and/or circuitry within the base substrate portion 616 or formed on a surface of the base substrate portion 616. In various embodiments, the conductive features 612 can comprise discrete pads or traces at least partially embedded in the inorganic bonding layer 618, which forms non-conductive field regions. In some embodiments, the conductive contact features can comprise exposed contact surfaces of through substrate vias (e.g., through silicon vias (TSVs)). In some embodiments, prior to dielectric bonding, portions of the conductive features 614 can be recessed below the non-conductive bonding surface 608 of the dielectric field region or non-conductive bonding layers 622. For example, in some embodiments, portions of the conductive features 614 can be recessed by less than 10 nm, less than 8 nm, less than 5 nm, or less than 3 nm, for example, recessed in a range of 0 nm to 10 nm, or in a range of 2 nm to 5 nm. The recess can be at or near the middle or center of the cavity in which the conductive features 614 are disposed, and, additionally or alternatively, can extend or be disposed along sides of the cavity in which the conductive features 614 are disposed. In other embodiments, however, the conductive features 614 are not recessed below the organic bonding surface 608. Instead, the conductive features 614 can be generally flush with the organic bonding surface 608.

In some embodiments, the organic bonding surface 608 can be prepared for bonding. For example, in some embodiments, the organic bonding surface 608 can be planarized and or polished until the organic bonding surface 608 is flat and/or smooth. In other embodiments, however, the organic bonding surface 608 may not be planarized or polished.

As shown in FIG. 6G, at block 516, the organic bonding surface 608 is exposed to oxygen plasma to terminate the organic bonding surface 608 with additional chemical species that the organofunctional groups of the silane coupling agent can bond to. For example, in some embodiments, the organic bonding surface 608 is exposed to an oxygen plasma to terminate the organic bonding surface 608 with hydroxyl groups. In other embodiments, the organic bonding surface 608 can be exposed to a plasma other than oxygen plasma and the organic bonding surface 608 can be terminated with other species besides hydroxyl groups.

In the illustrated embodiment, the organic bonding surface 608 is terminated with the chemical species by exposing the organic bonding surface 608 to a plasma. In other embodiments, however, the organic bonding surface 608 can be terminated with chemical species without exposing the organic bonding surface to plasma. For example, in some embodiments, the organic bonding surface 608 can be terminated with carboxyl groups by exposing the organic bonding surface 608 to carboxylic acid. In still other embodiments, the organic bonding surface 608 may not be terminated with chemical species prior to bonding the organic bonding surface 608 to the interface layer 610. For example, in some embodiments, silane coupling agent can include an organofunctional group that can covalently bond to the organic dielectric material that the organic bonding layer 622 is formed from.

As shown in FIG. 6H, at block 518, the organic bonding surface 608 is brought into contact with the interface layer 610 to form the bonded structure 600. As described above in connection with FIG. 2, when the organic bonding surface 608 contacts the interface layer 610, the organofunctional groups in the interface layer 610 can react with the organic bonding surface 608. For example, in some embodiments, the organofunctional groups can comprise epoxy groups and contacting the organic bonding surface 608 to the interface layer 610 can cause the epoxide groups to undergo an epoxy ring opening reaction that results in the interface layer 610 being covalently bonded to the organic bonding layer 622.

In some embodiments, the organic bonding surface 608 is brought into contact with the interface layer 610 to form the bonded structure 600 without applying any additional pressure (e.g., without applying any additional pressure beyond what is necessary to bring the organic bonding surface 608 in contact with the interface layer 610). In these embodiments, after contacting the organic bonding surface to the interface layer 610, no additional pressure may be applied to the second element 604 to facilitate bonding between the organic bonding surface 608 and the interface layer 610. In other embodiments, however, pressure can be applied to the second element 604 after the organic bonding surface 608 contacts the interface layer 610. For example, in some embodiments, pressure can be applied to the back side of the second element 604 (e.g., the surface of the second element 604 defined by the base substrate portion 620 and that opposes the organic bonding surface 608) after the organic bonding surface 608 contacts the interface layer 610 so as to facilitate bonding and improve bond strength between organic bonding surface 608 and the interface layer 610.

When the organic bonding surface 608 is brought into contact with the interface layer 610 to form the bonded structure 600, the conductive features 612, 614 can be separated from each other by a gap 630. In embodiments where the conductive features 612, 614 are flush with the respective bonding surfaces 606, 608, the gap 630 can be approximately equal to a thickness of interface layer 610 such that the conductive features 612, 614 are spaced apart from each other by a distance approximately equal to the thickness of the interface layer 610. However, in embodiments where one or both of the conductive features 612, 614 are recessed below their respective bonding surfaces 606, 608, the gap 630 can be larger than the thickness of the interface layer 610 such that the conductive features 612, 614 are spaced apart from each other by a distance greater than the thickness of the interface layer 610. For example, in some embodiments, a distance between the conductive features 612, 614 can be 15 nm or less, 10 nm or less, 5 nm or less, 1 to 15 nm, 3 to 12 nm, 5 to 10 nm, 3 to 5 nm, 10 to 15 nm, or a thickness in a range defined by any of these values.

At block 520, the bonded structure 600 is heated to anneal the bonded structure and to cause the conductive features 612, 614 to contact each other and form a metal-to-metal direct bond. In some embodiments, the bonded structure 600 is heated at a temperature of 180° C. for 1.5 hours. In other embodiments, the bonded structure 600 is heated at a different temperature for a different amount of time. For example, in some embodiments, the bonded structure 600 is heated at a temperature of 100° C. to 250° C., 100° C. to 150° C., 150° C. to 200° C., 200° C. to 250° C., 180° C., to 250° C., or a value in a range defined by any of these values, and is heated for 1 to 2 hours, 1 to 1.5 hours, 1.5 to 2 hours, 1.25 to 1.75, or a value in a range defined by any of these values. Heating the bonded structure 600 can also cause the conductive features 612, 614 to expand and contact one another to form a metal-to-metal direct bond. As shown in FIG. 6I after annealing the bonded structure, the conductive features 612, 614 can bond together to form conductive features 632 that do not include a gap. When the heated conductive features 612, 614 expand and contact each other, the materials of the conductive features 612, 614 (e.g., copper) can interdiffuse. In various embodiments, the metal-to-metal bonds between the conductive features 612, 614 can be joined such that metal grains grow into each other across the bond interface. In some embodiments, the metal is or includes copper, which can have grains oriented along the 111 crystal plane for improved copper diffusion across the bond interface. In some embodiments, the conductive features 612, 614 may include nanotwinned copper grain structure, which can aid in merging the conductive features during annealing. In some embodiments, when the bonded structure is heated, the organic bonding layer 622 can also expand, which can increase the size of the gap between the conductive features 612, 614. Accordingly, in some embodiments, the amount that the conductive features 612, 614 are recessed below their respective bonding surfaces 606, 608 prior to bonding can account for the expansion of the organic bonding layer 622 during annealing.

Additionally, as described above in connection with FIG. 2, heating the bonded structure 600 can increase the rate at which the organofunctional groups bond to the organic bonding surface 608 and to increase the bonding strength between the interface layer 610 and the organic bonding surface 608. Accordingly, in some embodiments, the bonded structure 600 can be heated in two different heating steps. For example, in some embodiments, the bonded structure 600 can be heated in a first heating step at 100° C. to 200° C. for a time of 30 minutes to 1 hour to facilitate bonding between the organic bonding surface 608 and the interface layer 610 and can then be heated in a second heating step at 150° C. to 250° C. for a time of 30 minutes to 2 hours to facilitate the formation of metal-to-metal direct bonds between the conductive features 612, 614. In some embodiments, heating the bonded structure 600 in the first heating step can comprise heating the bonded structure to a first temperature and heating the bonded structure 600 in the second heating step can comprise heating the bonded structure to a second temperature that is greater than the first temperature. In some embodiments, the bonded structure 600 can be cooled after the first heating step (e.g., cooled to a temperature less than the first temperature) and then heated to the second temperature in the second heating step. In other embodiments, the bonded structure 600 can be heated to the second temperature in the second heating step directly after the first heating step without allowing the bonded structure 600 to cool. In still other embodiments, only a single heating step can be used to anneal the bonded structure 600.

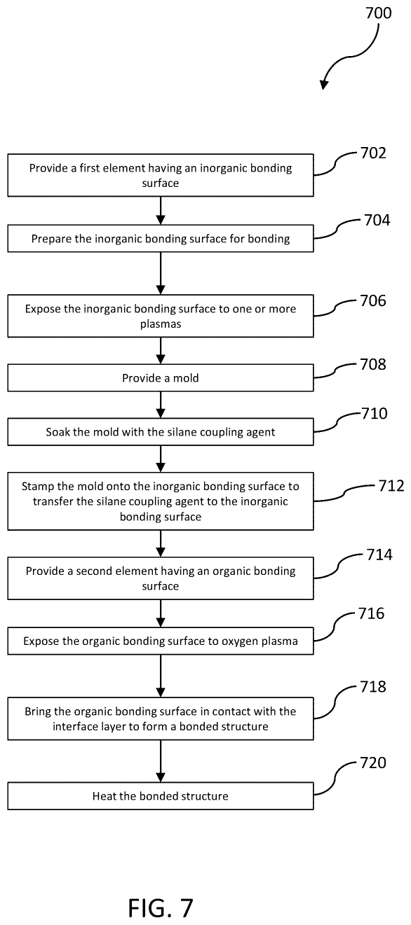

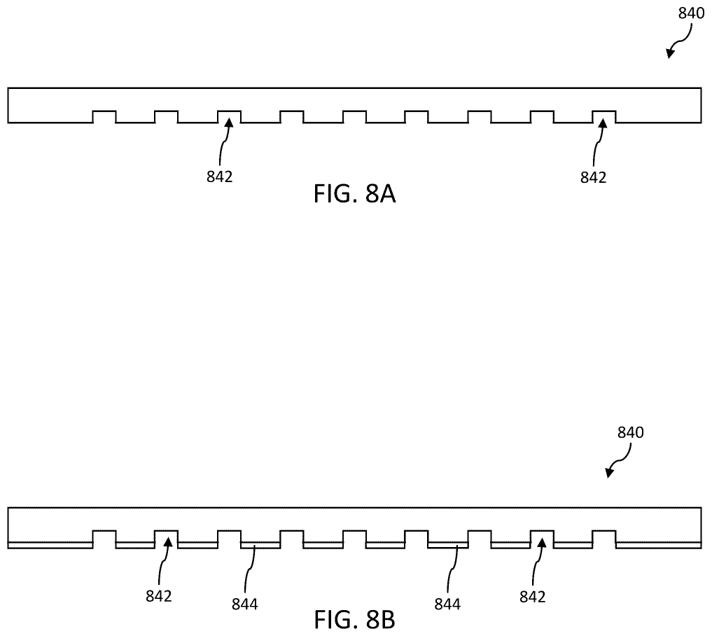

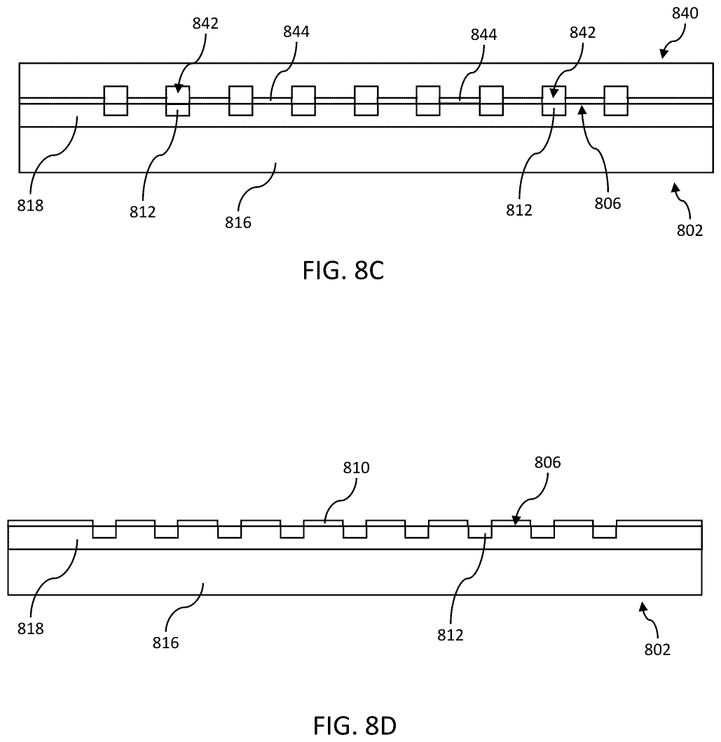

In the embodiments described above in connection with FIG. 5 and shown in FIGS. 6A-6I, the interface layer is formed by forming a photoresist over the conductive features, applying the silane coupling agent over the entire top surface of the first element, and then stripping away the photoresist to expose the conductive features. In other embodiments, however, the interface layer can be formed using a different process. FIG. 7 is a flowchart illustrating a process 700 for bonding a first element having an inorganic bonding surface to a second element having an organic bonding surface with an interface layer that is formed from a silane coupling agent formed using a mold. FIGS. 8A-8D are schematic side sectional views of various blocks of the process 700 shown in FIG. 7. Unless otherwise noted, the blocks of process 700 may be generally similar to the blocks of FIG. 5 and the features of the microelectronic components shown in FIGS. 8A-8D may be generally similar to the features of the components shown in FIGS. 6A-6I.

At block 702, a first element having an inorganic bonding surface is provided. At block 704, the inorganic bonding surface is prepared for bonding. At block 706, the inorganic bonding surface is exposed to one or more plasmas to activate and/or terminate the inorganic bonding surface. Blocks 702, 704, and 706 may be generally similar to blocks 502, 504, and 506 of FIG. 5 and the first element can be generally similar to first element 602 shown and described above in connection with FIGS. 6A-6I.

At block 708, a mold 840 is provided. The mold 840 can be formed from a polymer material such as polydimethylsiloxane (PDMS) and has a relief pattern formed in the mold. The mold 840 includes channels 842 formed in the polymer material that define the relief pattern. The relief pattern generally corresponds with the shape and layout of the conductive features in the first element such that, when the mold 840 is positioned over the first element, the channels 842 are positioned over the conductive features. In some embodiments, the mold 840 also includes alignment marks that can be used to align the mold 840 with the first element to ensure that the channels 842 are sufficiently aligned with the conductive features.

At block 710, the mold 840 can be soaked with the silane coupling agent 844. As shown in FIG. 8B, the silane coupling agent 844 can adhere to the mold 840 without filling the channels 842 such that, after soaking the mold with the silane coupling agent 844, only the unpatterned portions of the mold 840 have the silane coupling agent on them.

As shown in FIG. 8C, at block 712, the silane coupling agent is transferred to the inorganic bonding surface 806 of the first element 802, which includes a base substrate portion 816 and an inorganic bonding layer 818, by stamping the mold 840 onto the inorganic bonding surface 806. The mold 840 can be stamped onto the inorganic bonding surface 806 by aligning the mold 840 over the first element 802 (e.g., using alignment marks formed in the mold 840 and/or the first element 802) such that the channels 842 are positioned over the conductive features 812. The mold 840 is then pressed into the inorganic bonding surface 806 so that the silane coupling agent 844 adhered to the mold 840 contacts the inorganic bonding surface 806 without contacting the conductive features 812. Contacting the silane coupling agent 844 to the inorganic bonding surface 806 can cause the silane coupling agent to transfer to the inorganic bonding surface, which can cause the silane coupling agent to bond to the inorganic bonding surface and form the interface layer, as described above in connection with FIG. 6C. As shown in FIG. 8D, after the mold 840 is removed from the inorganic bonding surface 806, the silane bonding agent remains bonded to the inorganic bonding surface 806 and forms the interface layer 810. In some embodiments, after removing the mold 840, the first element 802 is heated to facilitate the formation of the interface layer 810, as described above in connection with block 510 of FIG. 5 and FIG. 6C.

In some embodiments, the mold 840 is brought into contact with the inorganic bonding surface 806 without applying any additional pressure (e.g., without applying any additional pressure beyond what is necessary to bring the mold 840 in contact with the inorganic bonding surface 806). In these embodiments, after contacting the mold 840 to the inorganic bonding surface 806, no additional pressure may be applied to the mold 840 to facilitate the silane coupling agent being transferred to the inorganic bonding surface. In other embodiments, however, pressure can be applied to the mold 840 after the mold 840 contacts the inorganic bonding surface 806 to ensure that the silane coupling agent bonds to the inorganic bonding surface 806.

At block 714, a second element having an organic bonding surface is provided. At block 716, the organic bonding surface is exposed to oxygen plasma. At block 718, the organic bonding surface is brought into contact with the interface layer to forma bonded structure. At block 720, the bonded structure is heated. Blocks 714, 716, 718, and 720 may be generally similar to blocks 514, 516, 518, and 520 and the second element can be generally similar to second element 604 shown and described above in connection with FIGS. 6A-6I.

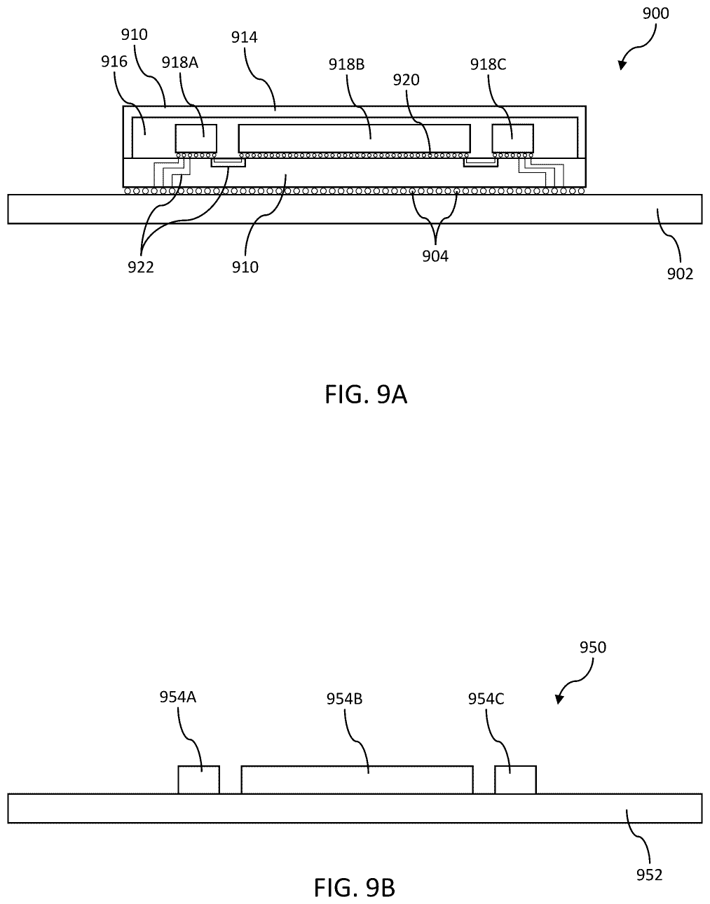

System substrates, including PCBs and flexible substrates, typically include an organic substrate and one or more devices (e.g., dies, die-containing packages, discrete surface mount components, etc.) attached to the substrate. In embodiments disclosed herein, the substrates have an organic bonding layer (e.g., a polymer-based bonding layer such as a polyimide bonding layer) that forms an organic bonding surface on which the one or more devices are attached. In conventional PCBs, the packages each include a package substrate and one or more dies attached to the substrate, which is then bonded to the PCB (e.g., with solder and/or an adhesive). The package substrate includes metallization structures (e.g., vias, bond pads, bridges) that facilitate communication between the individual devices and also between the devices and PCB substrate. FIG. 9A is a schematic side sectional view of a PCB 900 having a PCB substrate 902 and a package 910. The package 910 includes a package substrate 912, a package lid 914 which defines a cavity 916, and dies 918A-C within the cavity 916. The package 910 is attached to the PCB substrate with solder balls 904, which are positioned between the package substrate 912 and the PCB substrate 902. In some embodiments, an adhesive (e.g., an epoxy) is also used to attach the package 910 to the PCB substrate 902. The PCB substrate 902, which can have an organic bonding layer formed from an organic dielectric material (e.g., a polymer material such as polyimide), includes metallization structures (e.g., metal traces, contact pads) formed within the organic bonding layer and the solder balls 904 are bonded to some of these metallization structures (e.g., to contact pads below package substrate 906).

The package substrate 912 is typically formed from a ceramic material and includes various metallization structures 922 (e.g., vias, traces, bond pads, bridges) that are configured to electrically couple the dies 918A-C and the PCB substrate 902. The dies 918A-C are attached to the package substrate 906 with microbumps 920, which can be formed from copper and which are configured to electrically connect the dies 918A-C to the metallization structures 922. In some embodiments, an adhesive material (e.g., an epoxy material) may also be used to adhere the dies 918A-C to the package substrate 912. The metallization structures 922 include traces 924 that extend through the package substrate 912 between the microbumps 920 and the solder balls 904 and that are configured to electrically couple the dies 918A and 918C to the PCB substrate 902. The metallization structures 922 also include bridges 926 that are formed within the package substrate 912 and that are configured to electrically connect the dies 918A and 918C to the die 918B via microbumps 920. In some embodiments, the dies 918A and 918C comprise transceiver dies that are configured to transmit and receive signals between the circuit board substrate 902 (e.g., via the solder balls 904, the traces 924, and the microbumps 920) and the die 918B.

Microbumps are formed from small bumps of copper and provide electrical connection between bonded structures. However, microbumps are comparatively large and require a pitch of at least 20 μm between microbumps and typically have a pitch of about 40 μm. This relatively large pitch means that the density of I/O connections between the dies and the PCB substrate are limited. As dies get smaller and more complex, the need for higher density I/O connections to the dies increases. Additionally, in conventional systems, the package substrate 912 is needed to attach the dies 918A-C to the PCB substrate 902 because the dies 918A-C cannot be directly attached to the PCB substrate 902 without significant drawbacks. However, the package substrate 912 has a relatively large footprint and adds significant height to the PCB 900, which reduces the number of dies that can be attached to the PCB substrate 902.

FIG. 9B is a schematic side sectional view of a bonded structure 950 having a substrate 952 and plurality of microelectronic components 954A-C bonded to the substrate 952 without a package substrate. In some embodiments, the bonded structures 950 comprises a PCB and the substrate 952 comprises a PCB substrate (e.g., a flexible substrate). The substrate 952 includes an organic bonding layer and metallization structures (e.g., metal traces, contact pads) formed within the organic bonding layer, as described herein. The microelectronic components 954A-C comprise an inorganic bonding layer and metallization structures formed within the inorganic bonding layer, as described herein. The bonded structure 950 also includes one or more interface layers formed between the microelectronic components 954A-C and the substrate 952. The interface layer, which may be generally similar to the interface layer 110B described above in connection with FIG. 1B, is formed from a silane coupling agent and covalently bonds to both the organic bonding layer of the substrate 952 and the inorganic bonding layer of the microelectronic components 954A-C. The metallization structures in the organic and inorganic bonding layers include conductive features, including conductive bond pads of the substrate 952 and the conductive features of the microelectronic components 954A-C are directly bonded together to form a metal-to-metal bond and the bonded conductive features have a pitch of less than 20 am, less than 10 μm, less than 5 μm, less than 2 μm, 10 to 20 μm, 5 to 10 μm, 2-5 am, 2-20 am, 5-20 μm, or a value in a range defined by any of the values.

In accordance with one aspect of the present technology, a method of forming a bonded structure is provided. The method includes providing a first element and a second element. The first element has an inorganic dielectric surface and the second element has an organic dielectric surface. The method also includes exposing the inorganic dielectric surface to a silane coupling agent to form an interface layer and contacting the organic dielectric surface to the interface layer to bond the first element to the second element.

In some embodiments, the first element comprises a conductive feature, the inorganic dielectric surface comprises a non-conductive field region, and exposing the inorganic dielectric surface to the silane coupling agent comprises exposing the non-conductive field region to the silane coupling agent. In some embodiments, exposing the inorganic dielectric surface to the silane coupling agent comprises exposing the non-conductive field region to the silane coupling agent without exposing the conductive feature to the silane coupling agent. In some embodiments, exposing the non-conductive field region to silane coupling agent without exposing the conductive feature to the silane coupling agent comprises exposing at least 60% of the non-conductive field region to the silane coupling agent. In some embodiments, before exposing the inorganic dielectric surface to the silane coupling agent, forming a photoresist over the conductive feature, where the photoresist preventing the silane coupling agent from contacting the conductive feature, and then, after applying the silane coupling agent to the inorganic dielectric surface, removing the photoresist from conductive feature to expose the conductive feature. In some embodiments, the conductive feature comprises a first conductive feature, the second element comprises a second conductive feature, and the method further includes, after contacting the organic dielectric surface to the interface layer, bonding the first conductive feature to the second conductive feature. In some embodiments, bonding the first conductive feature to the second conductive feature comprises annealing the bonded first and second elements to cause the first and second conductive features to expand and contact each other. In some embodiments, the method further includes, after contacting the organic dielectric surface to the interface layer, heating the bonded first and second elements. In some embodiments, heating the bonded first and second elements comprises heating the bonded first and second elements to a first temperature and the method also includes, after heating the bonded first and second elements to the first temperature, heating the bonded first and second elements to a second temperature that is greater than the first temperature. In some embodiments, the first element comprises a first conductive feature exposed at the inorganic dielectric surface and the second element comprises a second conductive feature exposed at the organic dielectric surface and wherein heating the bonded first and second elements to the second temperature causes the first and second conductive features to expand and contact each other. In some embodiments, the method also includes before applying the silane coupling agent to the inorganic dielectric surface, forming hydroxyl groups on the inorganic dielectric surface. In some embodiments, forming hydroxyl groups on the inorganic dielectric surface comprises exposing the inorganic dielectric surface to an oxygen plasma. In some embodiments, the method also includes, before contacting the organic dielectric surface to the interface layer, forming hydroxyl groups on the organic dielectric surface. In some embodiments, the method also includes, before contacting the organic dielectric surface to the interface layer, forming carboxyl groups on the organic dielectric surface. In some embodiments, the silane coupling agent comprises a vinyl group, an epoxy group, an amino group, an isocyanate group, or a mercapto group. In some embodiments, the method also includes, before contacting the organic dielectric surface to the interface layer, planarizing at least one of the first and second elements. In some embodiments, planarizing at least one of the first and second elements comprises planarizing both of the first and second elements before contacting the organic dielectric surface to the interface layer. In some embodiments, the method also includes, after exposing the inorganic dielectric surface to the silane coupling agent but before contacting the organic dielectric surface to the interface layer, heating the inorganic dielectric surface to cause the silane coupling agent to covalently bond to the inorganic dielectric surface. In some embodiments, the interface layer is 15 nm thick or less. In some embodiments, the interface layer is 10 nm thick or less. In some embodiments, the interface layer is 5 nm thick or less.

In accordance with another aspect, a bonded structure is provided. The bonded structure includes a first element having an inorganic dielectric surface, a second element having an organic dielectric surface, and an interface layer between the first and second elements. The interface layer is bonded to the inorganic and organic dielectric surfaces and the interface layer is 15 nm thick or less.

In some embodiments, the second element comprises a polymer substrate. In some embodiments, organic dielectric surface does not include an oxide layer. In some embodiments, the interface layer is covalently bonded to the organic dielectric surface. In some embodiments, a bond strength between the first element and the interface layer is between 1 and 15 J/m2. In some embodiments, the second element comprises polyimide and the first element comprises silicon dioxide. In some embodiments, the inorganic dielectric surface comprises a non-conductive field region, the first element comprises a plurality of conductive features exposed at the inorganic dielectric surface, and the interface layer is bonded to the non-conductive field region without being bonded to the plurality of conductive features. In some embodiments, the interface layer is formed over at least 60% of the non-conductive field region. In some embodiments, the interface layer is formed over at least 90% of the non-conductive field region. In some embodiments, the interface layer comprises a first interface layer portion bonded to a first portion of the non-conductive field region and a second interface layer portion bonded to a second portion of the non-conductive field region, wherein the first and second portions of the non-conductive field region do not overlap. In some embodiments, the interface layer is about 10 nm thick or less. In some embodiments, the interface layer is about 5 nm thick or less. In some embodiments, the first element comprises a first conductive feature, the second element comprises a second conductive feature, and the first and second conductive features are directly bonded together.

In accordance with another aspect, a method is provided. The method includes providing a first element having an inorganic dielectric surface that includes a first non-conductive field region. The first element also comprises a first conductive feature exposed at the inorganic dielectric surface. The method further includes providing a second element having an organic dielectric surface that comprises a second non-conductive field region. The second element also comprises a second conductive feature exposed at the organic dielectric surface. The method further includes forming an interface layer over the inorganic dielectric surface. The interface layer has a thickness of 15 nm or less and at least partially covers the first non-conductive field region. The method further includes contacting the organic dielectric surface to the interface layer such that at least a portion of the second non-conductive field region contacts the interface layer and heating the first and second elements to cause the first and second conductive features to expand and contact each other. After heating the first and second elements, the first and second non-conductive field regions are both bonded to the interface layer.

In some embodiments, forming the interface layer over the inorganic dielectric surface comprises exposing the first non-conductive field region to a silane coupling agent. In some embodiments, forming the interface layer over the inorganic dielectric surface includes heating the inorganic dielectric surface to cause the silane coupling agent to covalently bond to the first non-conductive field region after exposing the first non-conductive field region to the silane coupling agent. In some embodiments, forming the interface layer over the inorganic dielectric surface comprises forming the interface layer such that it does not cover the first conductive feature. In some embodiments, contacting the organic dielectric surface to the interface layer comprises contacting the organic dielectric surface to the interface layer such that the second conductive feature does not contact the interface layer. In some embodiments, after heating the first and second elements, the first and second non-conductive field regions are both covalently bonded to the interface layer.

In another aspect, a method of forming a bonded structure. The method includes providing a first element having an inorganic dielectric surface and a first conductive feature, providing a second element having a polymer surface and a second conductive feature, treating the inorganic dielectric surface with a silane coupling agent, bonding the treated inorganic dielectric surface to the polymer surface by contacting the treated inorganic dielectric surface with the polymer surface such that the first and second conductive features face each other, and heating the first and second elements to cause the first and second conductive features to expand and contact each other.

In some embodiments, the inorganic dielectric surface comprises a non-conductive field region, and exposing the inorganic dielectric surface to the silane coupling agent comprises exposing the non-conductive field region to the silane coupling agent without exposing the conductive feature to the silane coupling agent.

In accordance with another aspect, a bonded structure is provided. The bonded structure includes a first element having an inorganic dielectric surface and a first conductive feature, a second element having an organic dielectric surface and a second conductive feature, and an interface layer between the inorganic dielectric surface and the organic dielectric surface. The interface layer is formed by exposing the inorganic dielectric surface to a silane coupling agent. The inorganic dielectric surface is covalently bonded to the interface layer such that a bond strength between the first element and the interface layer is between 1 and 15 J/m². The first and second conductive features are directly bonded to each other.

In some embodiments, the interface layer is 15 nm thick or less. In some embodiments, the organic dielectric surface is covalently bonded to the interface layer.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method of forming a bonded structure, the method comprising:
providing a first element having an inorganic dielectric surface;
providing a second element having an organic dielectric surface;
exposing the inorganic dielectric surface to a silane coupling agent to form an interface layer; and
contacting the organic dielectric surface to the interface layer to bond the first element to the second element.

2. The method of claim 1, wherein the first element comprises a conductive feature, wherein the inorganic dielectric surface comprises a non-conductive field region, and wherein exposing the inorganic dielectric surface to the silane coupling agent comprises exposing the non-conductive field region to the silane coupling agent.

3. The method of claim 2, wherein exposing the inorganic dielectric surface to the silane coupling agent comprises exposing the non-conductive field region to the silane coupling agent without exposing the conductive feature to the silane coupling agent.

4. The method of claim 3, wherein exposing the non-conductive field region to silane coupling agent without exposing the conductive feature to the silane coupling agent comprises exposing at least 60% of the non-conductive field region to the silane coupling agent.

5. The method of claim 3, further comprising:
before exposing the inorganic dielectric surface to the silane coupling agent, forming a photoresist over the conductive feature, the photoresist preventing the silane coupling agent from contacting the conductive feature; and
after applying the silane coupling agent to the inorganic dielectric surface, removing the photoresist from conductive feature to expose the conductive feature.

6. (canceled)

7. (canceled)

8. The method of claim 1, further comprising:
after contacting the organic dielectric surface to the interface layer, heating the bonded first and second elements.

9. The method of claim 8, wherein heating the bonded first and second elements comprises heating the bonded first and second elements to a first temperature, the method further comprising:
after heating the bonded first and second elements to the first temperature, heating the bonded first and second elements to a second temperature that is greater than the first temperature.

10. (canceled)

11. The method of claim 1, further comprising:
before applying the silane coupling agent to the inorganic dielectric surface, forming hydroxyl groups on the inorganic dielectric surface.

12. (canceled)

13. The method of claim 1, further comprising:
before contacting the organic dielectric surface to the interface layer, forming hydroxyl groups on the organic dielectric surface.

14. (canceled)

15. The method of claim 1, wherein the silane coupling agent comprises a vinyl group, an epoxy group, an amino group, an isocyanate group, or a mercapto group.

16. (canceled)

17. (canceled)

18. (canceled)

19. (canceled)

20. (canceled)

21. (canceled)

22. A bonded structure, comprising:
a first element having an inorganic dielectric surface;
a second element having an organic dielectric surface; and
an interface layer between the first and second elements and bonded to the inorganic and organic dielectric surfaces, wherein the interface layer is 15 nm thick or less.

23. The bonded structure of claim 22, wherein the second element comprises a polymer substrate.

24. (canceled)

25. The bonded structure of claim 22, wherein the interface layer is covalently bonded to the organic dielectric surface.

26. The bonded structure of claim 22, wherein a bond strength between the first element and the interface layer is between 1 and 15 J/m2.

27. The bonded structure of claim 22, wherein the second element comprises polyimide and the first element comprises silicon dioxide.

28. The bonded structure of claim 22, wherein the inorganic dielectric comprises surface a non-conductive field region, wherein the first element comprises a plurality of conductive features exposed at the inorganic dielectric surface, and wherein the interface layer is bonded to the non-conductive field region without being bonded to the plurality of conductive features.

29. The bonded structure of claim 28, wherein the interface layer is formed over at least 60% of the non-conductive field region.

30. (canceled)

31. (canceled)

32. (canceled)

33. The bonded structure of claim 22, wherein the interface layer is about 5 nm thick or less.

34. The bonded structure of claim 22, wherein the first element comprises a first conductive feature and the second element comprises a second conductive feature and wherein the first and second conductive features are directly bonded together.

35. A method of forming a bonded structure, the method comprising:
providing a first element having an inorganic dielectric surface that comprises a first non-conductive field region, wherein the first element comprises a first conductive feature exposed at the inorganic dielectric surface;
providing a second element having an organic dielectric surface that comprises a second non-conductive field region, wherein the second element comprises a second conductive feature exposed at the organic dielectric surface;
forming an interface layer over the inorganic dielectric surface, wherein the interface layer has a thickness of 15 nm or less and wherein the interface layer at least partially covers the first non-conductive field region;
contacting the organic dielectric surface to the interface layer such that at least a portion of the second non-conductive field region contacts the interface layer; and
heating the first and second elements to cause the first and second conductive features to expand and contact each other, wherein, after heating the first and second elements, the first and second non-conductive field regions are both bonded to the interface layer.

36. The method of claim 35, wherein forming the interface layer over the inorganic dielectric surface comprises exposing the first non-conductive field region to a silane coupling agent.

37. The method of claim 36, wherein forming the interface layer over the inorganic dielectric surface further comprises:
after exposing the first non-conductive field region to the silane coupling agent, heating the inorganic dielectric surface to cause the silane coupling agent to covalently bond to the first non-conductive field region.

38. The method of claim 35, wherein forming the interface layer over the inorganic dielectric surface comprises forming the interface layer such that it does not cover the first conductive feature.

39. (canceled)

40. The method of claim 35, wherein, after heating the first and second elements, the first and second non-conductive field regions are both covalently bonded to the interface layer.

41. (canceled)

42. (canceled)

43. (canceled)

44. (canceled)

45. (canceled)
